(19) United States
(12) Patent Application Publication
(10) Pub. No.: US 2025/0379107 A1
(43) Pub. Date: Dec. 11, 2025

(54) Method and System to Measure Optical Characteristics of Light-Transmissive Materials

(71) Applicant: Wolfspeed, Inc., Durham, NC (US)

(72) Inventor: Edward Lloyd Hutchins, Raleigh, NC (US)

(21) Appl. No.: 18/737,609

(22) Filed: Jun. 7, 2024

(51) Int. Cl. H01L 21/66; G01N 21/33; G01N 21/3563

(52) U.S. Cl. CPC H01L 22/20; G01N 21/33; G01N 21/3563; G01N 2201/0636

(57) ABSTRACT

Systems and methods for optical characteristic measurements are provided. In one example, a system includes one or more electromagnetic radiation sources, one or more reflectors, and at least one detector. The one or more electromagnetic radiation sources provide emission of one or more electromagnetic radiation signals to a workpiece such that each of the one or more electromagnetic radiation signals are at least partially transmitted through the workpiece. The one or more reflectors reflect the one or more electromagnetic radiation signals back through the workpiece such that the one or more electromagnetic radiation signals are transmitted through the workpiece a plurality of transmission instances. One or more characteristics of the workpiece may be determined based at least in part on the one or more electromagnetic radiation signals received at the at least one detector.

### FIELD

The present disclosure relates generally to optical characteristic measurements of light-transmissive materials, for instance, for use in semiconductor fabrication processes, optical component fabrication processes, electro-optical component fabrication processes, and/or the like.

### BACKGROUND

Windows, lenses, optical waveguides, and other devices may be manufactured from various workpieces, such as transparent workpieces. Various optical characteristics (e.g., absorption) and/or surface features of the workpieces are highly relevant for predicting final performance of the workpiece in its end-use application. Some systems, such as spectrometers, may be used to measure such optical characteristics (e.g., absorption) of the workpieces. However, these systems have a reduced capacity to accurately measure such optical measurements when the target workpiece exhibits highly transparent properties.

### SUMMARY

Aspects and advantages of embodiments of the present disclosure will be set forth in part in the following description, or can be learned from the description, or can be learned through practice of the embodiments.

In one aspect, the present disclosure provides an example method. In some implementations, the example method includes providing, from one or more electromagnetic radiation sources, emission of one or more electromagnetic radiation signals to a workpiece such that each of the one or more electromagnetic radiation signals are at least partially transmitted through the workpiece. In some implementations, the example method includes reflecting, with one or more reflectors, the one or more electromagnetic radiation signals back through the workpiece such that the one or more electromagnetic radiation signals are transmitted through the workpiece a plurality of transmission instances. In some implementations, the example method includes receiving the one or more electromagnetic radiation signals at at least one detector.

In another aspect, the present disclosure provides an example system. In some implementations, the example system includes one or more light sources operable to provide one or more light signals. In some implementations, the example system includes a workpiece holder operable to hold a semiconductor workpiece in an optical path of the one or more light sources such that each of the one or more light signals are at least partially transmitted through the semiconductor workpiece for a plurality of transmission instances. In some implementations, the example system includes one or more detectors operable to receive the one or more light signals subsequent to the plurality of transmission instances.

In another aspect, the present disclosure provides an example system. In some implementations, the example system includes a reflective structure comprising one or more reflectors. In some implementations, the example system includes one or more light sources operable to provide one or more light signals through a first channel of the reflective structure. In some implementations, the example system includes a workpiece holder operable to hold a workpiece in an optical path of the one or more light sources such that each of the one or more light signals at least partially transmit through the workpiece for a plurality of transmission instances. In some implementations, the example system includes one or more detectors operable to receive the one or more light signals through a second channel of the reflective structure subsequent to the plurality of transmission instances.

In another aspect, the present disclosure provides an example method. In some implementations, the example method includes providing, from one or more electromagnetic radiation sources, emission of one or more first electromagnetic radiation signals and one or more second electromagnetic radiation signals to a workpiece such that each of the one or more first electromagnetic radiation signals and each of the one or more second electromagnetic radiation signals are at least partially transmitted through the workpiece. In some implementations, the example method includes reflecting, with one or more reflectors, the one or more first electromagnetic radiation signals back through the workpiece such that each of the one or more first electromagnetic radiation signals are transmitted through a first location of the workpiece a first plurality of transmission instances. In some implementations, the example method includes reflecting, with the one or more reflectors, the one or more second electromagnetic radiation signals back through the workpiece such that each of the one or more second electromagnetic radiation signals are transmitted through a second location of the workpiece a second plurality of transmission instances. In some implementations, the example method includes, subsequent to the first plurality of transmission instances, receiving the one or more first electromagnetic radiation signals at a first detector and determining one or more characteristics of the workpiece at the first location based at least in part on the one or more first electromagnetic radiation signals. In some implementations, the example method includes, subsequent to the second plurality of transmission instances, receiving the one or more second electromagnetic radiation signals at a second detector and determining one or more characteristics of the workpiece at the second location based at least in part on the one or more second electromagnetic radiation signals.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a cross-sectional view of an example system for determining one or more characteristics of a workpiece according to example embodiments of the present disclosure;

FIGS. 2A-2D depict top plan views of example reflective structures according to example embodiments of the present disclosure;

FIG. 3 depicts a cross-sectional view of an example system for determining one or more characteristics of a workpiece according to example embodiments of the present disclosure;

FIG. 4 depicts a cross-sectional view of an example system for determining one or more characteristics of a workpiece according to example embodiments of the present disclosure;

FIG. 5 depicts a cross-sectional view of an example system for determining one or more characteristics of a workpiece according to example embodiments of the present disclosure;

FIG. 6 depicts a cross-sectional view of an example system for determining one or more characteristics of a workpiece according to example embodiments of the present disclosure;

FIG. 7 depicts a cross-sectional view of an example system for determining one or more characteristics of a workpiece according to example embodiments of the present disclosure;

FIG. 8 depicts a cross-sectional view of an example system for determining one or more characteristics of a workpiece according to example embodiments of the present disclosure;

FIG. 9 depicts a cross-sectional view of an example system for determining one or more characteristics of a workpiece according to example embodiments of the present disclosure;

FIG. 10 depicts a flow chart diagram of an example method according to example embodiments of the present disclosure; and

FIG. 11 depicts a flow chart diagram of an example method according to example embodiments of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Example aspects of the present disclosure generally relate to measuring and determining one or more characteristics of a workpiece, such as a semiconductor workpiece. More particularly, example aspects of the present disclosure provide a system that is operable to accurately measure and determine one or more characteristics of light-transmissive workpieces based at least in part on one or more electromagnetic radiation signals that are transmitted through the workpiece. For instance, as will be discussed in greater detail below, a system of the present disclosure may be operable to determine one or more spectroscopy metrics of a workpiece, one or more optical characteristics of a workpiece, one or more surface features of a workpiece, and/or the like.

In some examples, the example system described herein is operable to accurately measure and determine one or more characteristics of a “high-transparency” workpiece, which is a workpiece that has an absorption coefficient for one or more electromagnetic radiation signals in a wavelength range of interest (e.g., between about 1 nanometer to about 25 microns) of less than about 10 percent. In some examples, the absorption coefficient threshold of the workpiece may change to greater than 10 percent based on a number of factors, such as final application (e.g., use), desired transmissivity, and/or the like. For instance, in some examples, a “high-transparency” workpiece may have an absorption coefficient for the one or more electromagnetic radiation signals in the wavelength range of interest of greater than 10 percent, such as an absorption coefficient in a range of about 10 percent to about 50 percent, such as a range of about 10 percent to about 40 percent, such as a range of about 10 percent to about 30 percent, such as a range of about 10 percent to about 20 percent.

In some applications, a higher absorption coefficient may be desired (e.g., as opposed to a lower absorption coefficient), and in such applications, it may be desirable for the workpiece to have an absorption coefficient that is greater than the absorption coefficient threshold (e.g., 10 percent). Additionally and/or alternatively, in some applications, it may be desirable for a workpiece to have uniform transmissivity across the workpiece independent of and/or dependent on the absorption coefficient in the wavelength range of interest.

The absorption coefficient may be determined as an average across a wavelength range (e.g., the wavelength range of interest). Additionally and/or alternatively, the absorption coefficient may be determined at a particular wavelength of interest (e.g., within the wavelength range of interest). Additionally and/or alternatively, the absorption coefficient may be determined based on one or more electromagnetic radiation signals passing through the workpiece one time. Additionally and/or alternatively, the absorption coefficient may be determined based on one or more electromagnetic radiation signals passing through the workpiece more than one time. Additionally and/or alternatively, the absorption coefficient may be determined at a central portion of the workpiece. Additionally and/or alternatively, the absorption coefficient may be determined at a peripheral portion of the workpiece.

Some systems, such as spectrometers, may be used to determine characteristics and/or properties of a workpiece, such as various optical characteristics (e.g., optical absorption) of the workpiece. For instance, optical spectrometers may be used to determine various optical characteristics of workpieces by providing electromagnetic radiation (e.g., light) to a workpiece. The provided electromagnetic radiation may interact with the workpiece by being reflected by, absorbed by, or transmitted through the workpiece. Subsequently, due to how the electromagnetic radiation changes during its interaction with the workpiece (e.g., reflection, refraction, absorption), one or more characteristics and/or properties of the workpiece may be determined by measuring the wavelengths and/or intensity of the electromagnetic radiation that interacts with the workpiece.

However, spectrometers and other optical measurement systems have a reduced capacity to provide quick, stable, and accurate optical measurements of a workpiece and/or workpiece. More particularly, spectrometers and other optical measurement systems typically include an electromagnetic radiation source (e.g., light source) that provides electromagnetic radiation signals to a single point on the workpiece. Thus, such spectrometers and optical measurement systems are only operable to measure the optical characteristics and/or properties at one discrete location on the workpiece, which may not be representative of (or consistent with) the true optical characteristics and/or properties of the workpiece as a whole. Hence, measurements must be taken at a plurality of different locations on the workpiece in order to accurately measure the entire workpiece. Moreover, the spectrometer and/or other measurement system must be recalibrated (e.g., moving diffraction grading(s), detector(s), light source(s), etc.) in order to measure the optical characteristics at the plurality of different locations on the workpiece, which is a slow and labor-intensive process and may also introduce more inaccuracies into the measurements.

Moreover, these measurement constraints are further exacerbated when measuring a highly transparent workpiece and/or workpiece. More particularly, when measuring a highly-transparent workpiece, a significant portion of the electromagnetic radiation provided by the electromagnetic radiation source is transmitted through the workpiece. The resulting electromagnetic radiation signal received at the detector (e.g., absorption signal) may have a relatively low signal-to-noise ratio (SNR). Moreover, because the majority of the electromagnetic radiation signal is transmitted through the workpiece in a highly transmissive example, a single pass through the workpiece does not affect the electromagnetic radiation signal in a meaningful way to provide information about one or more optical characteristics of the workpiece. As such, in order to determine the one or more optical characteristics of a highly-transparent workpiece, the resulting absorption signal must undergo significant signal processing (e.g., integration) over a long period of time, which is costly and prone to inaccuracies.

Accordingly, example aspects of the present disclosure provide systems and methods for quickly and accurately determining one or more characteristics of a workpiece, such as a light-transmissive semiconductor workpiece, a highly-transparent semiconductor workpiece, and/or the like. As will be discussed in greater detail below, an example system of the present disclosure may include one or more electromagnetic radiation sources (e.g., one or more light sources) operable to provide one or more electromagnetic radiation signals (e.g., one or more light signals) and one or more detectors operable to receive the one or more electromagnetic radiation signals. The system may further include a workpiece holder operable to hold a workpiece, such as a semiconductor workpiece, in an optical path of the one or more electromagnetic radiation sources such that each of the one or more electromagnetic radiation signals are at least partially transmitted through the workpiece for a plurality of transmission instances. It should be understood that, as used herein, a “transmission instance” refers to each instance the one or more electromagnetic radiation signals at least partially transmit all the way through the workpiece and pass through two different surfaces of the workpiece.

The system may further include a measurement system. As will be discussed in greater detail below, the measurement system may include a reflective structure having one or more reflectors in the optical path of the one or more electromagnetic radiation sources. The reflector(s) may have any suitable shape, such as, by way of non-limiting example, a flat shape, an elliptical shape, a parabolic shape, a curved shape, and/or the like. Moreover, the measurement system and reflective structure may include any number of reflectors, such as one reflector and/or a plurality of reflectors.

For instance, by way of non-limiting example, an example measurement system may include a first reflector in parallel with a second reflector, and the workpiece may be between the first reflector and the second reflector. The measurement system and reflective structure may be in the optical path of the one or electromagnetic radiation sources such that the one or more electromagnetic radiation signals provided by the one or more electromagnetic radiation sources pass through the workpiece more than one time. For instance, due to the angle of the electromagnetic radiation signals incident on the workpiece, the one or more electromagnetic radiation signals may pass through the workpiece, reflect off one of the reflectors, and then pass back through the workpiece multiple times for multiple transmission instances (e.g., at different locations) before ultimately being collected by the one or more detectors.

The example system may further include one or more processors configured to determine one or more characteristics of the workpiece based at least in part on the one or more electromagnetic radiation signals received at the one or more detectors. More particularly, with each transmission instance through the workpiece, the information contained in the resulting electromagnetic radiation signals may be amplified. As such, the electromagnetic radiation signals that pass through the workpiece are more sensitive to the optical characteristics and/or the surface features of the workpiece. In this way, an example system of the present disclosure (e.g., via the one or more processors) may be operable to determine the one or more characteristics of the workpiece, such as one or more spectroscopy metrics, one or more optical metrics, one or more surface features, and/or the like.

Aspects of the present disclosure provide a number of technical effects and benefits. For instance, example aspects of the present disclosure provide fast, simple, stable, and accurate measurements of workpieces, such as high-transparency workpieces. More particularly, by providing a system having a measurement system that includes a reflective structure, electromagnetic radiation signals provided by the electromagnetic radiation sources pass through the workpiece multiple times. As such, one or more characteristics of the workpiece may be determined at multiple locations on the workpiece, which results in a stronger signal received at the detector that is more sensitive to the optical properties and surface features of the workpiece as a whole. In this way, the optical characteristics and surface features of the workpiece may be determined without extensive signal processing, which allows for faster measurements (e.g., particularly for high-transparency workpieces). Furthermore, due to the increased speed of the measurements and the increased signal strength of the signals received at the detector, example aspects of the present disclosure may be implemented in high-volume manufacturing environments, such as automated manufacturing environments. Additionally, the stronger signals received at the detector further provide for easier detection of differences between different workpieces, gauge calibration and maintenance, and quality control.

It will be understood that, although the terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or workpiece is referred to as being “on” or extending “onto” another element, it may be directly on or extend directly onto the other element or intervening elements may also be present. In contrast, when an element is referred to as being “directly on” or extending “directly onto” another element, there are no intervening elements present, except in some examples an attach material (e.g., die-attach material, solder, paste, adhesive, sintered material or other material may be present. It will also be understood that when an element is referred to as being “connected” or “coupled” to another clement, it may be directly connected or coupled to the other element or intervening elements may be present. In contrast, when an element is referred to as being “directly connected” or “directly coupled” to another element, there are no intervening elements present, except in some examples an attach material (e.g., die-attach material, solder, paste, adhesive, sintered material or other material may be present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments of the disclosure. The thickness of layers and regions in the drawings may be exaggerated for clarity. Additionally, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to silicon carbide-based semiconductor structures, such as silicon carbide-based MOSFETs. Those of ordinary skill in the art, using the disclosures provided herein, will understand that the power semiconductor packages according to example embodiments of the present disclosure may be used with any semiconductor material, such as other wide band gap semiconductor materials, without deviating from the scope of the present disclosure. Example wide band gap semiconductor materials include silicon carbide (e.g., 2.996 eV band gap for alpha silicon carbide at room temperature) and the Group III-nitrides (e.g., 3.36 eV band gap for gallium nitride at room temperature).

In the drawings and specification, there have been disclosed typical embodiments and, although specific terms are employed, they are used in a generic and descriptive sense only and not for purposes of limitation of the scope set forth in the following claims.

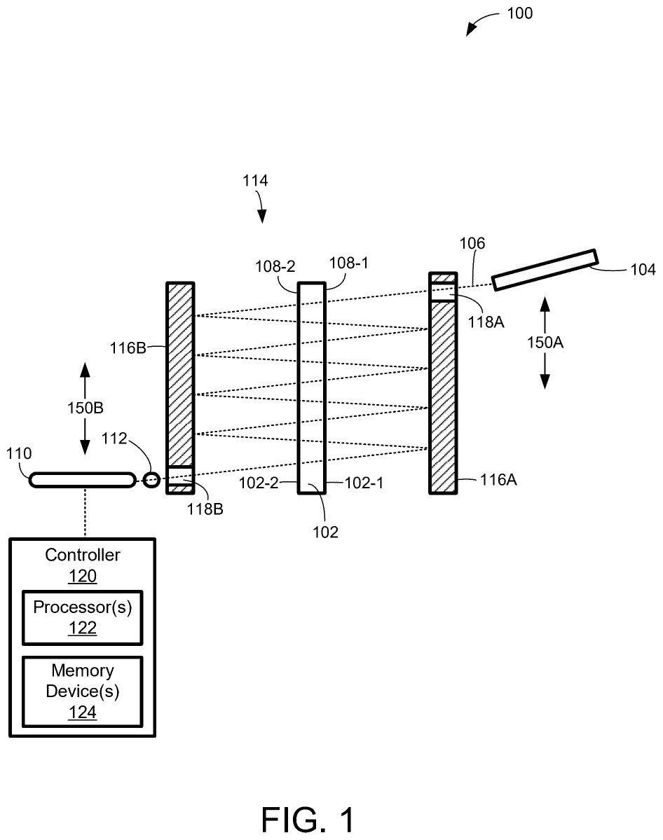

FIG. 1 depicts a cross-sectional view of an example system 100 for determining one or more characteristics of a workpiece 102 according to example embodiments of the present disclosure. For instance, as will be discussed in greater detail below, the system 100 may be operable to determine a spectroscopy metric for the workpiece 102, one or more surface features of the workpiece 102, and/or the like. It should be understood that FIG. 1 is intended to represent structures for purposes of identification and description and is not intended to represent the structures to physical scale.

The system 100 may include one or more electromagnetic radiation sources, such as light source 104, operable to provide one or more electromagnetic radiation signals, such as one or more light signals 106. It should be understood that, although described as including a light source 104, the system 100 may include any suitable electromagnetic radiation source that is operable to provide one or more electromagnetic radiation signals. Furthermore, although depicted as having one electromagnetic radiation source (e.g., light source 104), those having ordinary skill in the art, using the disclosures provided herein, will understand that the example system 100 may include any number of electromagnetic radiation sources without deviating from the scope of the present disclosure.

In some examples, the light source 104 may emit electromagnetic radiation (e.g., light signals 106) across an infrared (IR) wavelength band (e.g., an IR spectral band). Those having ordinary skill in the art will understand that the IR wavelength band includes wavelengths in a range of about 750 nanometers to about 25 microns. Additionally and/or alternatively, in some examples, the light source 104 may emit electromagnetic radiation (e.g., light signals 106) across a visible light wavelength band (e.g., a visible light spectral band). Those having ordinary skill in the art will understand that the visible light wavelength band includes wavelengths in a range of about 400 nanometers to about 750 nanometers. Additionally and/or alternatively, in some examples, the light source 104 may emit electromagnetic radiation (e.g., light signals 106) across an ultraviolet (UV) wavelength band (e.g., a UV spectral band). Those having ordinary skill in the art will understand that the UV wavelength band includes wavelengths in a range of about 1 nanometer to about 400 nanometers.

Additionally and/or alternatively, in some examples, the light source 104 may be a laser. More particularly, in some examples, the light source 104 may be a blue laser operable to emit electromagnetic radiation (e.g., light signals 106) in a blue spectral band. Those having ordinary skill in the art will understand that the blue spectral band includes wavelengths in a range of about 400 nanometers to about 500 nanometers. Additionally and/or alternatively, in some examples, the light source 104 may be a green laser operable to emit electromagnetic radiation (e.g., light signals 106) in a green spectral band. Those having ordinary skill in the art will understand that the green spectral band includes wavelengths in a range of about 500 nanometers to about 570 nanometers. Additionally and/or alternatively, in some examples, the light source 104 may be a red laser operable to emit electromagnetic radiation (e.g., light signals 106) in a red spectral band. Those having ordinary skill in the art will understand that the red spectral band includes wavelengths in a range of about 620 nanometers to about 750 nanometers.

Additionally and/or alternatively, in some examples, the light source 104 may be a monochromatic light source. More particularly, in some examples, the light source 104 may be a high-intensity light-emitting diode (LED). Other suitable light sources may be used without deviating from the scope of the present disclosure, such as a laser light source.

The system 100 may include a workpiece holder (not shown) that is operable to hold the workpiece 102 in an optical path (represented by the one or more light signals 106) of the light source 104. More particularly, the workpiece holder (not shown) may hold the workpiece 102 in the optical path of the light source 104 such that each of the one or more light signals 106 are at least partially transmitted all the way through the workpiece 102 for a plurality of transmission instances. As noted above, a transmission instance corresponds to each instance the one or more light signals 106 transmit through the workpiece 102 through at least two different surfaces. In some examples, the light source 104 may be stationary for the plurality of transmission instances. In some examples, the light source 104 may move during the plurality of transmission instances (e.g., as represented by arrow 150A). Furthermore, each transmission instance of the plurality of transmission instances may occur at a different location on the workpiece 102.

For instance, by way of non-limiting illustrative example, a first transmission instance may occur at a first location 108-1 on the workpiece 102, and a second transmission instance may occur at a second location 108-2 on the workpiece 102. It should be understood that only the first location 108-1 and the second location 108-2 are labeled in FIG. 1 for case of illustration and discussion. Furthermore, the plurality of transmission instances may define a total measurement area for the workpiece 102, which may, in some examples, include about 10 percent of a surface area of a major surface (e.g., major surface 102-1, major surface 102-2) of the workpiece 102.

In some examples, the workpiece 102 may be a semiconductor workpiece, such as silicon carbide semiconductor workpiece (e.g., a crystalline silicon carbide semiconductor workpiece). For instance, by way of non-limiting example, the workpiece 102 may be a high-transparency silicon carbide wafer. Additionally and/or alternatively, in some examples, the workpiece 102 may be a sapphire workpiece. Additionally and/or alternatively, in some examples, the workpiece 102 may be a glass workpiece. Additionally and/or alternatively, in some examples, the workpiece 102 may be a quartz workpiece. Additionally and/or alternatively, in some examples, the workpiece 102 may be an alumina workpiece. Additionally and/or alternatively, in some examples, the workpiece 102 may be a moissanite workpiece. Additionally and/or alternatively, in some examples, the workpiece 102 may be a diamond workpiece. In some examples, the workpiece 102 may be any suitable workpiece having an absorption coefficient for the one or more light signals 106 of less than about 10 percent. However, those having ordinary skill in the art, using the disclosures provided herein, will understand that the workpiece 102 may include any suitable light-transmissive material without deviating from the scope of the present disclosure.

In some examples, the workpiece 102 may be a substantially circular workpiece. In such examples, the workpiece 102 may have a diameter in a range of about 50 millimeters to about 300 millimeters, such as about 125 millimeters to about 275 millimeters, such as about 150 millimeters to about 200 millimeters. Additionally and/or alternatively, in some examples, the workpiece 102 may be a non-circular workpiece. In such examples, the workpiece 102 may have a workpiece area in a range of about 20 square centimeters (cm²) to about 800 square centimeters (cm²), such as about 100 square centimeters (cm²) to about 600 square centimeters (cm²), such as about 150 square centimeters (cm²) to about 400 square centimeters (cm²). However, those having ordinary skill in the art, using the disclosures provided herein, will understand that the workpiece 102 may have any suitable diameter and/or workpiece arca without deviating from the scope of the present disclosure. It should be understood that, as used herein, the “workpiece area” of a workpiece (e.g., workpiece 102) may refer to a surface area of a major surface of the workpiece (e.g., major surface 102-1 of the workpiece 102, major surface 102-2 of the workpiece 102, etc.).

The system 100 may include one or more detectors, such as detector 110, operable to receive the one or more light signals 106 subsequent to the plurality of transmission instances. In some examples, the detector 110 may be stationary for the plurality of transmission instances. In some examples, the detector 110 may move during the plurality of transmission instances (e.g., as represented by arrow 150B). In some examples, the detector 110 may be a charge-coupled device (CCD) detector. Additionally and/or alternatively, in some examples, the detector 110 may be a photomultiplier tube (PMT). However, the detector 110 may be any suitable detector without deviating from the scope of the present disclosure. Furthermore, in some examples, the system 100 may include one or more optical filters 112 between the semiconductor workpiece 102 and the detector 110.

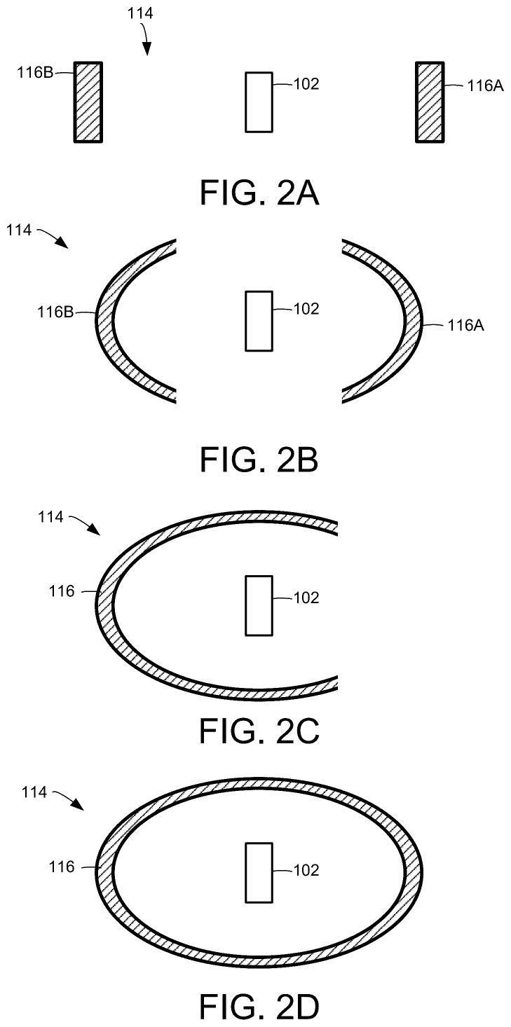

The system 100 may further include a measurement system, such as reflective structure 114. It should be understood that the terms “measurement system” and “reflective structure” may be used interchangeably. More particularly, the reflective structure 114 may include one or more reflectors 116 in the optical path of the light source 104. For instance, as shown, the system 100 may include a first reflector 116A in parallel with a second reflector 116B. The workpiece holder and, hence, the workpiece 102 may be between the first reflector 116A and the second reflector 116B. As discussed in greater detail below (FIGS. 2A-2D), the reflectors 116 of the reflective structure 114 may have any suitable shape, configuration, and/or the like.

As shown, the light source 104 may be operable to provide the one or more light signals 106 through a first channel 118A in the first reflector 116A such that each of the one or more light signals 106 at least partially transmit all the way through the workpiece 102 and reflect off the second reflector 116B; subsequent to the plurality of transmission instances, the detector 110 may receive the one or more light signals 106 through a second channel 118B in the second reflector 116B.

The system 100 may include one or more control devices, such as a controller 120. The controller 120 may include one or more processors 122 and one or more memory devices 124. The controller 120 may be in communication with various aspects of the system 100 through one or more wired and/or wireless links. The one or more processors 122 may include any suitable processing device (e.g., a processor core, a microprocessor, an application specific integrated circuit (AISC), a field programmable gate array (FPGA), a microcontroller, etc.) and may be one processor or a plurality of processors that are operatively connected. The one or more memory devices 124 may include one or more non-transitory computer-readable storage media, such as random-access memory (RAM), read-only memory (ROM), electronically erasable programmable ready-only memory (EEPROM), erasable programmable read-only memory (EPROM), flash memory devices, and combinations thereof. The one or more memory devices 124 may store data and computer-readable instructions that, when executed by the one or more processors 122, cause the one or more processors 122 to perform operations, such as any of the operations described herein.

For instance, the one or more processors 122 may be configured to determine a spectroscopy metric of the workpiece 102 based at least in part on the one or more light signals 106 received by the detector 110, such as an optical absorption metric for the workpiece 102, an optical density of the workpiece 102, a transmittance of the workpiece 102, an optical reflectance of the workpiece 102, and/or the like. The one or more processors 122 may further be configured to determine one or more surface features of the workpiece 102 (e.g., major surface 102-1, major surface 102-2) based at least in part on the one or more light signals 106 received by the detector 110, such as a surface roughness of the workpiece 102, a parallelism of the workpiece 102, an optical wedge on one or more of the surfaces of the workpiece 102, and/or the like. In some examples, the one or more processors 122 may be further configured to determine a characteristic distribution across the workpiece 102 based at least in part on the spectroscopy metric and/or the one or more surface features.

As noted above, the reflectors 116 of the reflective structure 114 may have any suitable shape, configuration, and/or the like. By way of non-limiting example, FIGS. 2A-2D top plan views of example reflective structures 114 of the system 100 (FIG. 1) according to example embodiments of the present disclosure. It should be understood that FIGS. 2A-2D are intended to represent structures for purposes of identification and description and are not intended to represent the structures to physical scale.

By way of non-limiting example, as shown in FIG. 2A, each of the one or more reflectors 116 of the reflective structure 114 may a flat shape, and the workpiece 102 may be therebetween. Additionally and/or alternatively, as shown in FIG. 2B, each of the one or more reflectors 116 may have a curved shape, and the workpiece 102 may be therebetween. Additionally and/or alternatively, as shown in FIG. 2C, each of the one or more reflectors 116 may have a parabolic shape, and the workpiece 102 may be therebetween. Additionally and/or alternatively, as shown in FIG. 2D, each of the one or more reflectors 116 may have an elliptical shape, and the workpiece 102 may be therebetween.

FIGS. 2A-2D depict example reflective structures 114 for purposes of illustration and discussion. Those having ordinary skill in the art, using the disclosures provided herein, will understand that different reflective structures 114 may be used without deviating from the scope of the present disclosure.

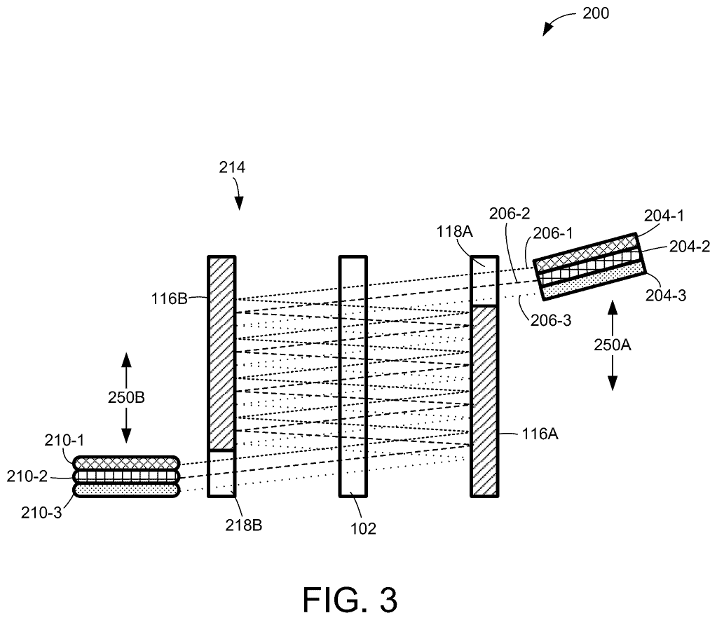

As noted above, some example systems may include more than one electromagnetic radiation source (e.g., light source 104) and more than one detector (e.g., detector 110). As one illustrative example, FIG. 3 depicts a cross-sectional view of an example system 200 for determining one or more characteristics of the workpiece 102 according to example embodiments of the present disclosure. It should be understood that the example system 200 may be similar to the example system 100 described above with reference to FIGS. 1-2D. For instance, as described above with reference to the system 100 (FIGS. 1-2D), the system 200 may be operable to determine a spectroscopy metric for the workpiece 102, one or more surface features of the workpiece 102, and/or the like. It should be understood that FIG. 3 is intended to represent structures for purposes of identification and description and is not intended to represent the structures to physical scale.

As noted above, the system 200 may be similar to the system 100 (FIGS. 1-2D). For instance, the system 200 may include a workpiece holder (not shown) operable to hold the workpiece 102. The workpiece 102 may be any suitable workpiece 102, such as a silicon carbide semiconductor workpiece (e.g., crystalline silicon carbide semiconductor workpiece, high-transparency silicon carbide wafer, etc.), a sapphire workpiece, a glass workpiece, a moissanite workpiece, a diamond workpiece, a quartz workpiece, an alumina workpiece, and/or the like. Moreover, the workpiece 102 may have any suitable shape, such as a substantially circular shape, a non-circular shape, and/or the like. For instance, in some examples, the workpiece 102 may have a diameter in a range of about 50 millimeters to about 300 millimeters, such as a range of about 125 millimeters to about 275 millimeters, such as a range of about 150 millimeters to about 200 millimeters. Additionally and/or alternatively, in some examples, the workpiece 102 may have a workpiece area in a range of about 20 square centimeters (cm²) to about 800 square centimeters (cm²), such as about 100 square centimeters (cm²) to about 600 square centimeters (cm²), such as about 150 square centimeters (cm²) to about 400 square centimeters (cm²).

The system 200 may also include a measurement system, such as the reflective structure 114. The reflective structure 114 may include one or more reflectors, such as the first reflector 116A and the second reflector 116B. It should be understood that, although depicted and described as having first reflector 116A and second reflector 116B, the reflector 116 of the reflective structure 114 may have any suitable shape, configuration, and/or the like. By way of non-limiting example, the reflective structure 114 may have any of the configurations described above with reference to FIGS. 2A-2D.

However, in contrast to the system 100, the system 200 may include more than one electromagnetic radiation source. More particularly, the system 200 may include a first electromagnetic radiation source 204-1, a second electromagnetic radiation source 204-2, and a third electromagnetic radiation source 204-3 (collectively, “electromagnetic radiation sources 204”). The electromagnetic radiation sources 204 may be similar to the light source 104 described above with reference to FIG. 1. For instance, the electromagnetic radiation sources 204 may be one or more lasers, one or more monochromatic light sources, and/or the like. Moreover, the electromagnetic radiation sources 204 may emit electromagnetic radiation (e.g., electromagnetic radiation signals 206-1, 206-2, 206-3) in the IR wavelength band, the visible light wavelength band, and/or the UV wavelength band. In some examples, such as that depicted in FIG. 3, the electromagnetic radiation sources 204 may provide emission of the electromagnetic radiation signals 206 through the first channel 118A in the first reflector 116A.

By way of illustrative example, the first electromagnetic radiation source 204-1 may provide emission of one or more first electromagnetic radiation signals 206-1. The one or more first electromagnetic radiation signals 206-1 may at least partially transmit all the way through the workpiece 102 for the plurality of transmission instances. In some examples, the first electromagnetic radiation source 204-1 may be an infrared (IR) radiation source operable to emit one or more first electromagnetic radiation signals 206-1 in an IR spectral band, such as the IR wavelength band described above with reference to FIG. 1. Additionally and/or alternatively, in some examples, the first electromagnetic radiation source 204-1 may be a blue laser radiation source operable to emit one or more first electromagnetic radiation signals 206-1 in a blue spectral band, such as the blue spectral band described above with reference to FIG. 1.

By way of additional illustrative example, the second electromagnetic radiation source 204-2 may provide emission of one or more second electromagnetic radiation signals 206-2. The one or more second electromagnetic radiation signals 206-2 may at least partially transmit all the way through the workpiece 102 for the plurality of transmission instances. In some examples, the second electromagnetic radiation source 204-2 may be a visible light radiation source operable to emit one or more second electromagnetic radiation signals 206-2 in a visible light spectral band, such as the visible light wavelength band described above with reference to FIG. 1. Additionally and/or alternatively, in some examples, the second electromagnetic radiation source 204-2 may be a green laser radiation source operable to emit one or more second electromagnetic radiation signals 206-2 in a green spectral band, such as the green spectral band described above with reference to FIG. 1.

By way of additional illustrative example, the third electromagnetic radiation source 204-3 may provide emission of one or more third electromagnetic radiation signals 206-3. The one or more third electromagnetic radiation signals 206-3 may at least partially transmit all the way through the workpiece 102 for the plurality of transmission instances. In some examples, the third electromagnetic radiation source 204-3 may be an ultraviolet (UV) radiation source operable to emit one or more third electromagnetic radiation signals 206-3 in a UV spectral band, such as the UV wavelength band described above with reference to FIG. 1. Additionally and/or alternatively, in some examples, the third electromagnetic radiation source 204-3 may be a red laser radiation source operable to emit one or more third electromagnetic radiation signals 206-3 in a red spectral band, such as the red spectral band described above with reference to FIG. 1.

In some examples, each of the electromagnetic radiation sources 204 may be stationary for the plurality of transmission instances. In some examples, each of the electromagnetic radiation sources 204 may move during the plurality of transmission instances (e.g., as indicated by arrow 250A). In some examples, at least one of the electromagnetic radiation sources 204 may move during the plurality of transmission instances (e.g., as indicated by arrow 250A), while at least one of the other electromagnetic radiation sources 204 remains stationary. By way of non-limiting example, the first electromagnetic radiation source 204-1 may be stationary for the plurality of transmission instances, and at least one of the second electromagnetic radiation source 204-2 and/or the third electromagnetic radiation source 204-3 may move along a path represented by arrow 250A.

Furthermore, in contrast to the system 100, the system 200 may include more than one detector. More particularly, the system 200 may include a first detector 210-1, a second detector 210-2, and a third detector 210-3 (collectively “detectors 210”). The detectors 210 may be similar to the detector 110 described above with reference to FIG. 1. For instance, the detectors 210 may be charge-coupled device (CCD) detectors, photomultiplier tubes (PMTs), and/or the like. In some examples, each of the detectors 210 may be stationary for the plurality of transmission instances. In some examples, each of the detectors 210 may move during the plurality of transmission instances (e.g., as represented by arrow 250B). In some examples, at least one of the detectors 210 may move during the plurality of transmission instances (e.g., as indicated by arrow 250B), while at least one of the other detectors 210 remains stationary. By way of non-limiting example, the first detector 210-1 may be stationary for the plurality of transmission instances, and at least one of the second detector 210-2 and/or the third detector 210-3 may move along a path represented by arrow 250B.

In some examples, such as that depicted in FIG. 3, the first detector 210-1 may be operable to receive the one or more first electromagnetic radiation signals 206-1 emitted by the first electromagnetic radiation source 204-1. Additionally and/or alternatively, in some examples, the second detector 210-2 may be operable to receive the one or more second electromagnetic radiation signals 206-2 emitted by the second electromagnetic radiation source 204-2. Additionally and/or alternatively, in some examples, the third detector 210-3 may be operable to receive the one or more third electromagnetic radiation signals 206-3 emitted by the third electromagnetic radiation source 204-3.

In some examples, although not depicted in FIG. 3, the system 200 may include one or more optical filters (e.g., one or more optical filters 112 (FIG. 1)) between the workpiece 102 and the detectors 210. In such examples, subsequent to the plurality of transmission instances, the one or more optical filters (not shown) may be operable to filter the one or more electromagnetic radiation signals 206; subsequent to the filtering of the one or more electromagnetic radiation signals 206, the detectors 210 may be operable to receive the one or more electromagnetic radiation signals 206.

Like the system 100 (FIG. 1), the system 200 may include one or more processors (not shown) (e.g., processor(s) 122 (FIG. 1)) configured to determine one or more characteristics of the workpiece 102 based at least in part on the one or more electromagnetic radiation signals 206 received by the detectors 210. More particularly, the one or more processors (not shown) may be configured to determine a spectroscopy metric of the workpiece 102 based at least in part on the one or more electromagnetic radiation signals 206 received by the detectors 210, such as an optical absorption metric for the workpiece 102, an optical density of the workpiece 102, a transmittance of the workpiece 102, an optical reflectance of the workpiece 102, and/or the like. The one or more processors (not shown) may further be configured to determine one or more surface features of the workpiece 102 (e.g., major surface 102-1, major surface 102-2) based at least in part on the one or more electromagnetic radiation signals 206 received by the detectors 210, such as a surface roughness of the workpiece 102, a parallelism of the workpiece 102, an optical wedge on one or more of the surfaces of the workpiece 102, and/or the like.

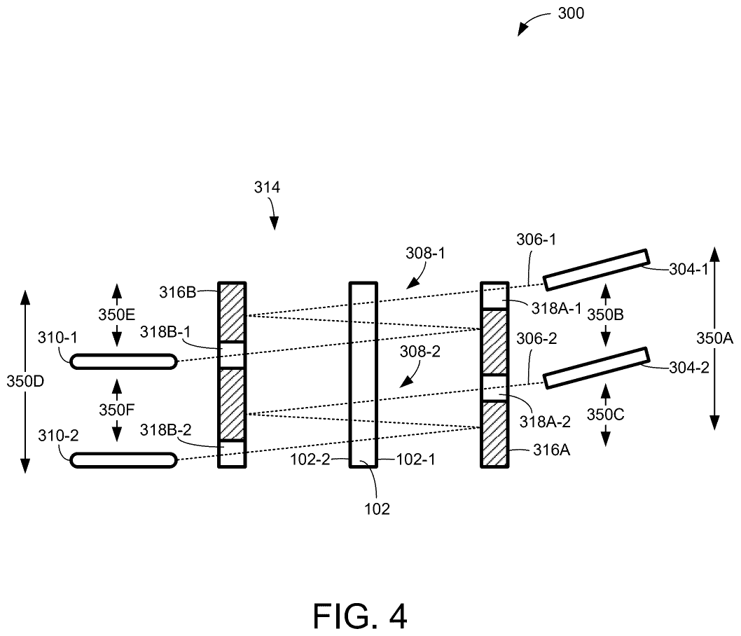

As noted above, in some examples, example systems may be operable to determine a characteristic distribution across the workpiece 102. As one illustrative example, FIG. 4 depicts a cross-sectional view of an example system 300 for determining one or more characteristics of the workpiece 102 according to example embodiments of the present disclosure. It should be understood that the example system 300 may be similar to the example system 100 described above with reference to FIGS. 1-2D and/or the system 200 described above with reference to FIG. 3. For instance, as described above with reference to the system 100 (FIGS. 1-2D) and the system 200 (FIG. 3), the system 300 may be operable to determine a spectroscopy metric for the workpiece 102, one or more surface features of the workpiece 102, and/or the like. It should be understood that FIG. 4 is intended to represent structures for purposes of identification and description and is not intended to represent the structures to physical scale.

As noted above, the system 300 may be similar to the system 100 (FIGS. 1-2D) and/or the system 200 (FIG. 3). For instance, the system 300 may include a workpiece holder (not shown) operable to hold the workpiece 102. The system 300 may also include one or more electromagnetic radiation sources, such as a first electromagnetic radiation source 304-1 and a second electromagnetic radiation source 304-2 (collectively “electromagnetic radiation sources 304”). The electromagnetic radiation sources 304 may be similar to any of the electromagnetic radiation sources described herein, such as the light source 104 (FIG. 1) and/or the electromagnetic radiation sources 204 (FIG. 3). The system 300 may also include one or more detectors, such as a first detector 310-1 and a second detector 310-2 (collectively “detectors 310”). The detectors 310 may be similar to any of the detectors described herein, such as the detector 110 (FIG. 1) and/or the detectors 210 (FIG. 3). Furthermore, although not depicted in FIG. 4, the system 300 may include one or more optical filters (e.g., one or more optical filters 112 (FIG. 1)) between the workpiece 102 and the detectors 310.

In some examples, each of the electromagnetic radiation sources 304 may be stationary for the plurality of transmission instances. In some examples, each of the electromagnetic radiation sources 304 may move during the plurality of transmission instances (e.g., as indicated by arrow 350A). In some examples, one of the electromagnetic radiation sources 304 may move during the plurality of transmission instances (e.g., as indicated by arrows 350B, 350C, respectively), while the other electromagnetic radiation source 304 remains stationary. By way of non-limiting example, the first electromagnetic radiation source 304-1 may be stationary for the plurality of transmission instances, and the second electromagnetic radiation source 304-2 may move along a path represented by arrow 350C. Conversely, in another non-limiting example, the second electromagnetic radiation 304-2 may be stationary for the plurality of transmission instances, and the first electromagnetic radiation source 304-1 may move along a path represented by arrow 350B.

Likewise, in some examples, each of the detectors 310 may be stationary for the plurality of transmission instances. In some examples, each of the detectors 310 may move during the plurality of transmission instances (e.g., as indicated by arrow 350D). In some examples, one of the detectors 310 may move during the plurality of transmission instances (e.g., as indicated by arrows 350E, 350F, respectively), while the other detector 310 remains stationary. By way of non-limiting example, the first detector 310-1 may be stationary for the plurality of transmission instances, and the second detector 310-2 may move along a path represented by arrow 350F. Conversely, in another non-limiting example, the second detector 310-2 may be stationary for the plurality of transmission instances, and the first detector 310-1 may move along a path represented by arrow 350E.

However, in contrast to the system 100 and the system 200, the system 300 may include a measurement system, such as the reflective structure 314. Like the reflective structure 114 discussed above (FIGS. 1-3), the reflective structure 314 may include one or more reflectors, such as a first reflector 316A and a second reflector 316B (collectively “reflector 316”). It should be understood that, although depicted and described as having first reflector 316A and second reflector 316B, the reflector 316 of the reflective structure 314 may have any suitable shape, configuration, and/or the like. By way of non-limiting example, the reflective structure 314 may have any of the configurations described above with reference to FIGS. 2A-2D.

The first electromagnetic radiation source 304-1 may provide emission of one or more first electromagnetic radiation signals 306-1 to the workpiece 102 such that each of the one or more first electromagnetic radiation signals 306-1 at least partially transmit all the way through the workpiece 102 at a first location 308-1 for a first plurality of transmission instances. More particularly, as shown, the first plurality of transmission instances may occur at the first location 308-1 on the workpiece 102. In some examples, such as that depicted in FIG. 4, the first electromagnetic radiation source 304-1 may provide emission of the one or more first electromagnetic radiation signals 306-1 through a first channel 318A-1 in the first reflector 316A.

Subsequent to the first plurality of transmission instances, the one or more first electromagnetic radiation signals 306-1 may be received at the first detector 310-1, and one or more processors (not shown) of the system 300 (e.g., processor(s) 122 (FIG. 1)) may determine one or more characteristics of the workpiece 102 at the first location 308-1. In some examples, such as that depicted in FIG. 4, the first detector 310-1 may receive the one or more first electromagnetic radiation signals 306-1 through a first channel 318B-1 in the second reflector 316B.

The second electromagnetic radiation source 304-2 may provide emission of one or more second electromagnetic radiation signals 306-2 to the workpiece 102 such that each of the one or more second electromagnetic radiation signals 306-2 at least partially transmit all the way through the workpiece 102 at a second location 308-2 for a second plurality of transmission instances. More particularly, as shown, the second plurality of transmission instances may occur at the second location 308-2 on the workpiece 102. In some examples, such as that depicted in FIG. 4, the second electromagnetic radiation source 304-2 may provide emission of the one or more second electromagnetic radiation signals 306-2 through a second channel 318A-2 in the first reflector 316A.

Subsequent to the second plurality of transmission instances, the one or more second electromagnetic radiation signals 306-2 may be received at the second detector 310-2, and one or more processors (not shown) of the system 300 (e.g., processor(s) 122 (FIG. 1)) may determine one or more characteristics of the workpiece 102 at the second location 308-2. In some examples, such as that depicted in FIG. 4, the second detector 310-2 may receive the one or more second electromagnetic radiation signals 306-2 through a second channel 318B-2 in the second reflector 316B.

The one or more processors (not shown) of the system 300 (e.g., processor(s) 122 (FIG. 1)) may be further configured to determine a characteristic distribution across the workpiece 102 subsequent to the first plurality of transmission instances and the second plurality of transmission instances. More particularly, in some examples, the one or more processors (not shown) (e.g., processor(s) 122 (FIG. 1)) may be configured to determine the characteristic distribution across the workpiece 102 based at least in part on the one or more characteristics at the first location 308-1 of the workpiece 102 and the one or more characteristics at the second location 308-2 of the workpiece 102.

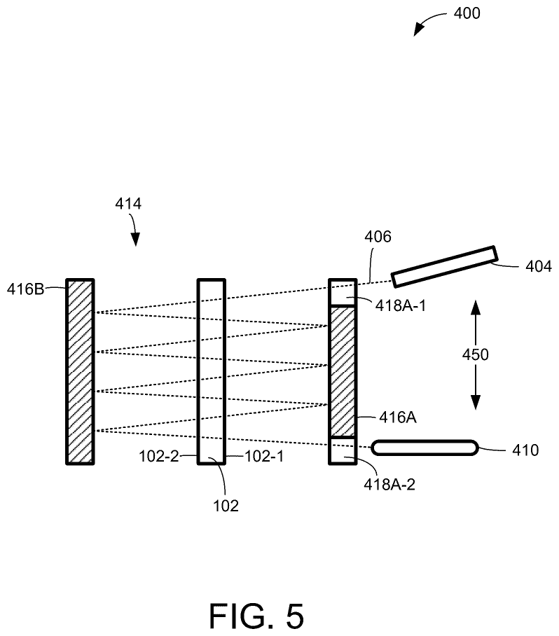

As noted above, in some examples, example systems may include a reflective structure having one or more reflectors, and at least one reflector of the one or more reflectors does not include a channel. As one illustrative example, FIG. 5 depicts a cross-sectional view of an example system 400 for determining one or more characteristics of the workpiece 102 according to example embodiments of the present disclosure. It should be understood that the example system 400 may be similar to any of the systems described herein, such as the system 100 (FIG. 1), the system 200 (FIG. 3), and/or the system 300 (FIG. 4). For instance, as described above with the reference to the example systems 100, 200, 300 (FIGS. 1, 3-4), the system 400 may be operable to determine a spectroscopy metric for the workpiece 102, one or more surface features of the workpiece 102, and/or the like. It should be understood that FIG. 5 is intended to represent structures for purposes of identification and description and is not intended to represent the structures to physical scale.

As noted above, the system 400 may be similar to the system 100 (FIG. 1), the system 200 (FIG. 3), and/or the system 300 (FIG. 4). For instance, the system 400 may include a workpiece holder (not shown) operable to hold the workpiece 102. The system 400 may also include one or more electromagnetic radiation sources, such as electromagnetic radiation source 404. The electromagnetic radiation source 404 may be similar to any of the electromagnetic radiation sources described herein, such as the light source 104 (FIG. 1), the electromagnetic radiation sources 204 (FIG. 3), and/or the electromagnetic radiation sources 304 (FIG. 4). The system 400 may also include one or more detectors, such as detector 410. The detector 410 may be similar to any of the detectors described herein, such as the detector 110 (FIG. 1), the detectors 210 (FIG. 3), and/or the detectors 310 (FIG. 4). Furthermore, although not depicted in FIG. 5, the system 400 may include one or more optical filters (e.g., one or more optical filters 112 (FIG. 1)) between the workpiece 102 and the detector 410.

In some examples, the electromagnetic radiation source 404 may be stationary for the plurality of transmission instances. In some examples, the electromagnetic radiation source 404 may move during the plurality of transmission instances (e.g., as represented by arrow 450). In some examples, the detector 410 may be stationary for the plurality of transmission instances. In some examples, the detector 410 may move during the plurality of transmission instances (e.g., as represented by arrow 450).

However, in contrast to the systems 100, 200, 300 (FIGS. 1, 3-4), the system 400 may include a measurement system, such as the reflective structure 414. Like the reflective structures 114, 314 (FIGS. 1-4), the reflective structure 414 may include one or more reflectors, such as a first reflector 416A and a second reflector 416B (collectively “reflector 416”). It should be understood that, although depicted and described as having first reflector 416A and second reflector 416B, the reflector 416 of the reflective structure 414 may have any suitable shape, configuration, and/or the like. By way of non-limiting example, the reflective structure 414 may have any of the configurations described above with reference to FIGS. 2A-2D.

Like the systems 100, 200, 300 (FIGS. 1, 3-4), the first reflector 416A may include a first channel 418A-1 through which the electromagnetic radiation source 404 provides emission of one or more electromagnetic radiation signals 406. However, in contrast to the systems 100, 200, 300 (FIGS. 1, 3-4), the second reflector 416B does not include any channels. More particularly, as shown, the detector 410 may receive the one or more electromagnetic radiation signals 406 through a second channel 418A-2 in the first reflector 416A.

Like the systems 100, 200, 300 (FIGS. 1, 3-4), the system 400 may include one or more processors (not shown) (e.g., processor(s) 122 (FIG. 1)) configured to determine one or more characteristics of the workpiece 102 based at least in part on the one or more electromagnetic radiation signals 406 received by the detectors 410. More particularly, the one or more processors (not shown) (e.g., processor(s) 122 (FIG. 1)) may be configured to determine a spectroscopy metric of the workpiece 102, such as any of the spectroscopy metrics described herein, and/or one or surface features of the workpiece 102, such as any of the surfaces features described herein, based at least in part on the one or more electromagnetic radiation signals 406 received by the detector 410.

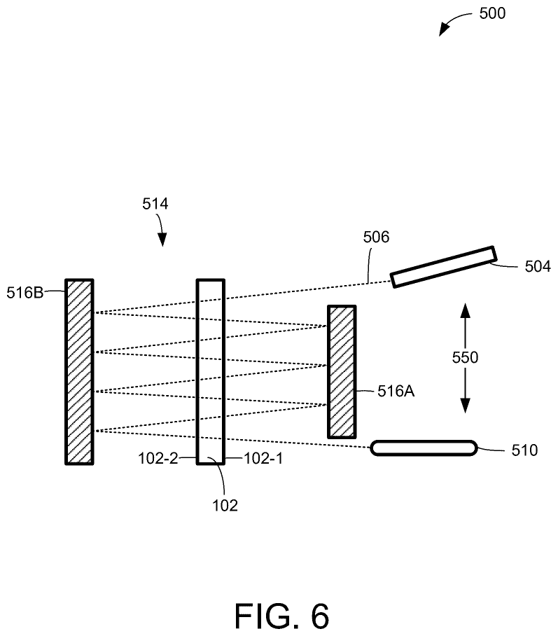

As noted above, in some examples, example systems may include a reflective structure that includes at least one or more reflectors, and no reflector of the one or more reflectors includes a channel. As one illustrative example, FIG. 6 depicts a cross-sectional view of an example system 500 for determining one or more characteristics of the workpiece 102 according to example embodiments of the present disclosure. It should be understood that the example system 400 may be similar to any of the systems described herein, such as the system 100 (FIG. 1), the system 200 (FIG. 3), the system 300 (FIG. 4), and/or the system 400 (FIG. 5). For instance, as described above with the reference to the example systems 100, 200, 300, 400 (FIGS. 1, 3-5), the system 500 may be operable to determine a spectroscopy metric for the workpiece 102, one or more surface features of the workpiece 102, and/or the like. It should be understood that FIG. 6 is intended to represent structures for purposes of identification and description and is not intended to represent the structures to physical scale.

As noted above, the system 500 may be similar to the system 100 (FIG. 1), the system 200 (FIG. 3), the system 300 (FIG. 4), and/or the system 400 (FIG. 5). For instance, the system 500 may include a workpiece holder (not shown) operable to hold the workpiece 102. The system 500 may also include one or more electromagnetic radiation sources, such as electromagnetic radiation source 504. The electromagnetic radiation source 504 may be similar to any of the electromagnetic radiation sources described herein, such as the light source 104 (FIG. 1), the electromagnetic radiation sources 204 (FIG. 3), the electromagnetic radiation sources 304 (FIG. 4), and/or the electromagnetic radiation source 404 (FIG. 5). The system 500 may also include one or more detectors, such as detector 510. The detector 510 may be similar to any of the detectors described herein, such as the detector 110 (FIG. 1), the detectors 210 (FIG. 3), the detectors 310 (FIG. 4), and/or the detector 410 (FIG. 5). Furthermore, although not depicted in FIG. 6, the system 500 may include one or more optical filters (e.g., one or more optical filters 112 (FIG. 1)) between the workpiece 102 and the detector 510.

In some examples, the electromagnetic radiation source 504 may be stationary for the plurality of transmission instances. In some examples, the electromagnetic radiation source 504 may move during the plurality of transmission instances (e.g., as represented by arrow 550). In some examples, the detector 510 may be stationary for the plurality of transmission instances. In some examples, the detector 510 may move during the plurality of transmission instances (e.g., as represented by arrow 550).

However, in contrast to the systems 100, 200, 300, 400 (FIGS. 1, 3-5), the system 500 may include a measurement system, such as the reflective structure 514. Like the reflective structures 114, 314, 414 (FIGS. 1-5), the reflective structure 514 may include one or more reflectors, such as a first reflector 516A and a second reflector 516B (collectively “reflector 516”). It should be understood that, although depicted and described as having first reflector 516A and second reflector 516B, the reflector 516 of the reflective structure 514 may have any suitable shape, configuration, and/or the like. By way of non-limiting example, the reflective structure 514 may have any of the configurations described above with reference to FIGS. 2A-2D.

In contrast to the systems 100, 200, 300, 400 (FIGS. 1, 3-5), neither the first reflector 516A nor the second reflector 516B includes a channel. More particularly, the electromagnetic radiation source 504 may provide emission of one or more electromagnetic radiation signals 506 that are subsequently received at the detector 510. However, the one or more electromagnetic radiation signals 506 are neither emitted through a channel in the reflector 516 (e.g., by the electromagnetic radiation source 504) nor received through a channel in the reflector 516 (e.g., at the detector 510).

Like the systems 100, 200, 300, 400 (FIGS. 1, 3-5), the system 500 may include one or more processors (not shown) (e.g., processor(s) 122 (FIG. 1)) configured to determine one or more characteristics of the workpiece 102 based at least in part on the one or more electromagnetic radiation signals 506 received by the detectors 510. More particularly, the one or more processors (not shown) (e.g., processor(s) 122 (FIG. 1)) may be configured to determine a spectroscopy metric of the workpiece 102, such as any of the spectroscopy metrics described herein, and/or one or surface features of the workpiece 102, such as any of the surfaces features described herein, based at least in part on the one or more electromagnetic radiation signals 506 received by the detectors 510.

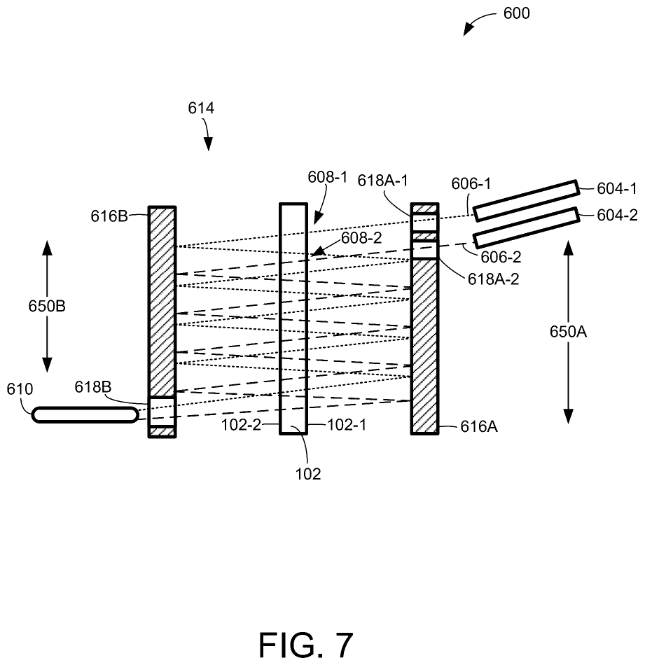

As noted above, in some examples, example systems may include mismatched numbers of electromagnetic radiation sources and detectors. As one illustrative example, FIG. 7 depicts a cross-sectional view of an example system 600 for determining one or more characteristics of the workpiece 102 according to example embodiments of the present disclosure. It should be understood that the example system 600 may be similar to any of the systems described herein, such as the system 100 (FIG. 1), the system 200 (FIG. 3), the system 300 (FIG. 4), the system 400 (FIG. 5), and/or the system 500 (FIG. 6). For instances, as described above with reference to the example systems 100, 200, 300, 400, 500 (FIGS. 1, 3-6), the system 600 may be operable to determine a spectroscopy metric for the workpiece 102, one or more surface features of the workpiece 102, and/or the like. It should be understood that FIG. 7 is intended to represent structures for purposes of identification and description and is not intended to represent the structures to physical scale.

As noted above, the system 600 may be similar to the system 100 (FIG. 1), the system 200 (FIG. 3), the system 300 (FIG. 4), the system 400 (FIG. 5), and/or the system 500 (FIG. 6). For instance, the system 600 may include a workpiece holder (not shown) operable to hold the workpiece 102. The system 600 may also include one or more electromagnetic radiation sources, such as a first electromagnetic radiation source 604-1 and a second electromagnetic radiation source 604-2 (collectively, “electromagnetic radiation sources 604”). The electromagnetic radiation sources 604 may be similar to any of the electromagnetic radiation sources described herein, such as the light source 104 (FIG. 1), the electromagnetic radiation sources 204 (FIG. 3), the electromagnetic radiation sources 304 (FIG. 4), the electromagnetic radiation source 404 (FIG. 5), and/or the electromagnetic radiation source 504 (FIG. 6). The system 600 may also include one or more detectors, such as detector 610. The detector 610 may be similar to any of the detectors described herein, such as the detector 110 (FIG. 1), the detectors 210 (FIG. 3), the detectors 310 (FIG. 4), the detector 410 (FIG. 5), and/or the detector 510 (FIG. 6). Furthermore, although not depicted in FIG. 7, the system 600 may include one or more optical filters (e.g., one or more optical filters 112 (FIG. 1)) between the workpiece 102 and the detector 610.

In some examples, each of the electromagnetic radiation sources 604 may be stationary for the plurality of transmission instances. In some examples, each of the electromagnetic radiation sources 604 may move during the plurality of transmission instances (e.g., as indicated by arrow 650A). In some examples, one of the electromagnetic radiation sources 604 may move during the plurality of transmission instances (e.g., as indicated by arrow 650A), while the other electromagnetic radiation source 304 remains stationary. Likewise, in some examples, the detector 610 may be stationary for the plurality of transmission instances. In some examples, the detector 610 may move during the plurality of transmission instances (e.g., as represented by arrow 650B).

The system 600 may further include a measurement system, such as the reflective structure 614. The reflective structure 614 may be similar to any of the reflective structures and/or measurement systems described herein. For instance, in some examples, the reflective structure 614 may include one or more reflectors, such as a first reflector 616A and a second reflector 616B (collectively, “reflectors 616”). It should be understood that, although depicted and described as having first reflector 616A and second reflector 616B, the reflector 616 of the reflective structure 614 may have any suitable shape, configuration, and/or the like. By way of non-limiting example, the reflective structure 614 may have any of the configurations described above with reference to FIGS. 2A-2D.

In some examples, the first electromagnetic radiation source 604-1 may provide emission of one or more first electromagnetic radiation signals 606-1 to a first location 608-1 of the workpiece 102 such that each of the one or more first electromagnetic radiation signals 606-1 at least partially transmit all the way through the workpiece 102 for a plurality of transmission instances. Similarly, the second electromagnetic radiation source 604-2 may provide emission of one or more second electromagnetic radiation signals 606-2 to a second location 608-2 of the workpiece 102 such that each of the one or more second electromagnetic radiation signals 606-2 at least partially transmit all the way through the workpiece 102 for a plurality of transmission instances. In some examples, such as that depicted in FIG. 7, the first electromagnetic radiation source 604-1 may provide emission of the one or more first electromagnetic radiation signals 606-1 through a first channel 618A-1 in the first reflector 616A, and the second electromagnetic radiation source 604-2 may provide emission of the one or more second electromagnetic radiation signals 606-2 through a second channel 618A-2 in the first reflector 616A.

However, in contrast to the system 100, 200, 300, 400, 500 (FIGS. 1, 3-6), both the one or more first electromagnetic radiation signals 606-1 and the second electromagnetic radiation signals 606-2 may be received by the same detector (e.g., detector 610) following the plurality of transmission instances. In some examples, such as that depicted in FIG. 7, the detector 610 may receive both the one or more first electromagnetic radiation signals 606-1 and the one or more second electromagnetic radiation signals 606-2 through a channel 618B in the second reflector 616B.

Although depicted as including one or more channels (e.g., channels 618A-1, 618A-2, 618B) in the reflective structure, those having ordinary skill in the art, using the disclosures provided herein, will understand that the system 600 may include a reflective structure without channel(s) (e.g., reflective structure 514 (FIG. 6)) without deviating from the scope of the present disclosure.

Like the systems 100, 200, 300, 400, 500 (FIGS. 1, 3-6), the system 600 may include one or more processors (not shown) (e.g., processor(s) 122 (FIG. 1)) configured to determine one or more characteristics of the workpiece 102 based at least in part on the one or more first electromagnetic radiation signals 606-1 and the one or more second electromagnetic radiation signals 606-2 received by the detectors 610. More particularly, the one or more processors (not shown) (e.g., processor(s) 122 (FIG. 1)) may be configured to determine a spectroscopy metric of the workpiece 102, such as any of the spectroscopy metrics described herein, and/or one or surface features of the workpiece 102, such as any of the surfaces features described herein, based at least in part on the one or more first electromagnetic radiation signals 606-1 and the one or more second electromagnetic radiation signals 606-2 received by the detectors 610.

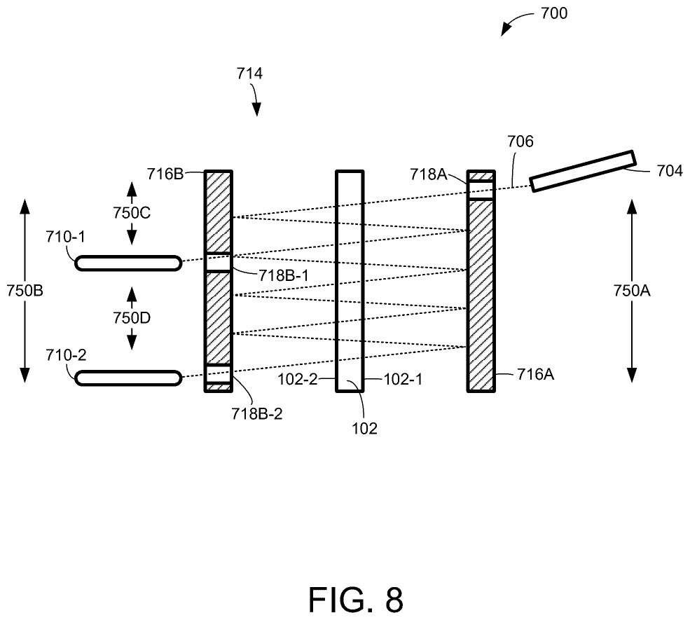

As an additional illustrative example, FIG. 8 depicts a cross-sectional view of an example system 700 for determining one or more characteristics of the workpiece 102 according to example embodiments of the present disclosure. It should be understood that the example system 700 may be similar to any of the systems described herein, such as the system 100 (FIG. 1), the system 200 (FIG. 3), the system 300 (FIG. 4), the system 400 (FIG. 5), the system 500 (FIG. 6), and/or the system 600 (FIG. 7). For instances, as described above with reference to the example systems 100, 200, 300, 400, 500, 600 (FIGS. 1, 3-7), the system 700 may be operable to determine a spectroscopy metric for the workpiece 102, one or more surface features of the workpiece 102, and/or the like. It should be understood that FIG. 8 is intended to represent structures for purposes of identification and description and is not intended to represent the structures to physical scale.

As noted above, the system 700 may be similar to the system 100 (FIG. 1), the system 200 (FIG. 3), the system 300 (FIG. 4), the system 400 (FIG. 5), the system 500 (FIG. 6), and/or the system 600 (FIG. 7). For instance, the system 700 may include a workpiece holder (not shown) operable to hold the workpiece 102. The system 700 may also include one or more electromagnetic radiation sources, such as electromagnetic radiation source 704. The electromagnetic radiation source 704 may be similar to any of the electromagnetic radiation sources described herein, such as the light source 104 (FIG. 1), the electromagnetic radiation sources 204 (FIG. 3), the electromagnetic radiation sources 304 (FIG. 4), the electromagnetic radiation source 404 (FIG. 5), the electromagnetic radiation source 504 (FIG. 6), and/or the electromagnetic radiation sources 604 (FIG. 7). The system 700 may also include one or more detectors, such as a first detector 710-1 and a second detector 710-2 (collectively, “detectors 710”). The detectors 710 may be similar to any of the detectors described herein, such as the detector 110 (FIG. 1), the detectors 210 (FIG. 3), the detectors 310 (FIG. 4), the detector 410 (FIG. 5), the detector 510 (FIG. 6), and/or the detector 610 (FIG. 7). Furthermore, although not depicted in FIG. 8, the system 700 may include one or more optical filters (e.g., one or more optical filters 112 (FIG. 1)) between the workpiece 102 and the detectors 710.

In some examples, the electromagnetic radiation source 704 may be stationary for the plurality of transmission instances. In some examples, the electromagnetic radiation source 704 may move during the plurality of transmission instances (e.g., as represented by arrow 750A). In some examples, each of the detectors 710 may be stationary for the plurality of transmission instances. In some examples, each of the detectors 710 may move during the plurality of transmission instances (e.g., as indicated by arrow 750B). In some examples, one of the detectors 710 may move during the plurality of transmission instances (e.g., as indicated by arrows 750C, 750D, respectively), while the other detector 710 remains stationary. By way of non-limiting example, the first detector 710-1 may be stationary for the plurality of transmission instances, and the second detector 710-2 may move along a path represented by arrow 750D. Conversely, in another non-limiting example, the second detector 710-2 may be stationary for the plurality of transmission instances, and the first detector 710-1 may move along a path represented by arrow 750C.

The system 700 may further include a measurement system, such as the reflective structure 714. The reflective structure 714 may be similar to any of the reflective structures and/or measurement systems described herein. For instance, in some examples, the reflective structure 714 may include one or more reflectors, such as a first reflector 716A and a second reflector 716B (collectively, “reflectors 716”). It should be understood that, although depicted and described as having first reflector 716A and second reflector 716B, the reflector 716 of the reflective structure 714 may have any suitable shape, configuration, and/or the like. By way of non-limiting example, the reflective structure 714 may have any of the configurations described above with reference to FIGS. 2A-2D.

In some examples, the electromagnetic radiation source 704 may provide emission of one or more electromagnetic radiation signals 706 to the workpiece 102 such that each of the one or more electromagnetic radiation signals 706 at least partially transmit all the way through the workpiece 102 for a plurality of transmission instances. In some examples, such as that depicted in FIG. 8, the electromagnetic radiation source 704 may provide emission of the one or more electromagnetic radiation signals 706 through a channel 718A in the first reflector 716A.

However, in contrast to the system 100, 200, 300, 400, 500, 600 (FIGS. 1, 3-7), the one or more electromagnetic radiation signals 706 may be received by multiple detectors at different locations (e.g., first detector 710-1, second detector 710-2) following the plurality of transmission instances. More particularly, as shown, the electromagnetic radiation source 704 may provide emission of the one or more electromagnetic signals 706, a first portion of which being received by the first detector 710-1 (e.g., through channel 718B-1 in the second reflector 718B) and a second portion of which being received by the second detector 710-2 (e.g., through channel 718B-2 in the second reflector 718B).

Although depicted as including one or more channels (e.g., channels 718A, 718B-1, 718B-2) in the reflective structure, those having ordinary skill in the art, using the disclosures provided herein, will understand that the system 700 may include a reflective structure without channel(s) (e.g., reflective structure 514 (FIG. 6)) without deviating from the scope of the present disclosure.

Like the systems 100, 200, 300, 400, 500, 600 (FIGS. 1, 3-7), the system 700 may include one or more processors (not shown) (e.g., processor(s) 122 (FIG. 1)) configured to determine one or more characteristics of the workpiece 102 based at least in part on the one or more electromagnetic radiation signals 706 received by both the first detector 710-1 and the second detector 710-2. More particularly, the one or more processors (not shown) (e.g., processor(s) 122 (FIG. 1)) may be configured to determine a spectroscopy metric of the workpiece 102, such as any of the spectroscopy metrics described herein, and/or one or surface features of the workpiece 102, such as any of the surfaces features described herein, based at least in part on the one or more electromagnetic radiation signals 706 received by both the first detector 710-1 and the second detector 710-2. In some examples, the one or more processors (not shown) (e.g., processor(s) 122 (FIG. 1)) may be further configured to determine a characteristic distribution across the workpiece 102 based at least in part on the spectroscopy metric and/or the one or more surface features.

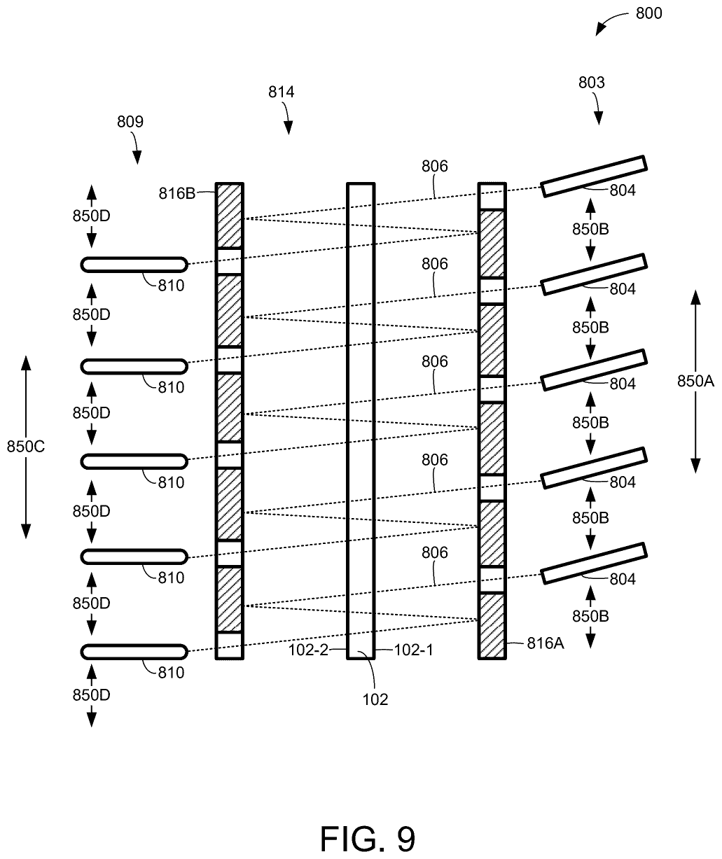

As noted above, in some examples, example systems may include an array of electromagnetic radiation sources and an array of detectors. As one illustrative example, FIG. 9 depicts a cross-sectional view of an example system 800 for determining one or more characteristics of the workpiece 102 according to example embodiments of the present disclosure. It should be understood that the example system 800 may be similar to any of the systems described herein, such as the system 100 (FIG. 1), the system 200 (FIG. 3), the system 300 (FIG. 4), the system 400 (FIG. 5), the system 500 (FIG. 6), the system 600 (FIG. 7), and/or the system 700 (FIG. 8). For instances, as described above with reference to the example systems 100, 200, 300, 400, 500, 600, 700 (FIGS. 1, 3-8), the system 800 may be operable to determine a spectroscopy metric for the workpiece 102, one or more surface features of the workpiece 102, and/or the like. It should be understood that FIG. 9 is intended to represent structures for purposes of identification and description and is not intended to represent the structures to physical scale.

As noted above, the system 800 may be similar to the system 100 (FIG. 1), the system 200 (FIG. 3), the system 300 (FIG. 4), the system 400 (FIG. 5), the system 500 (FIG. 6), the system 600 (FIG. 7), and/or the system 700 (FIG. 8). For instance, the system 800 may include a workpiece holder (not shown) operable to hold the workpiece 102. In contrast to the aforementioned systems, however, the system 800 may include an array 803 of electromagnetic radiation sources 804 and an array 809 of detectors 810. The array 803 of electromagnetic radiation sources 804 may include any of the electromagnetic radiation sources described herein, and the array 809 of detectors 810 may include any of the detectors described herein. Furthermore, although not depicted in FIG. 9, the system 800 may include an array of optical filters (e.g., array of optical filters 112 (FIG. 1)) between the workpiece 102 and the array 809 of detectors 810. It should be understood that the arrays 803, 809 may include any suitable number of electromagnetic radiation sources and detectors, respectively, without deviating from the scope of the present disclosure.

In some examples, the array 803 may be stationary for the plurality of transmission instances. In some examples, the array 803 may move during the plurality of transmission instances (e.g., as represented by arrow 850A). In some examples, one or more of the electromagnetic radiation sources 804 of the array 803 may move relative to other electromagnetic radiation sources 804 of the array 803 (e.g., as represented by arrow 850B). In some examples, the array 809 may be stationary for the plurality of transmission instances. In some examples, the array 809 may move during the plurality of transmission instances (e.g., as represented by arrow 850C). In some examples, one or more of the detectors 810 of the array 809 may move relative to other detectors 810 of the array 809 (e.g., as represented by arrow 850D).

The system 800 may further include a measurement system, such as the reflective structure 814. The reflective structure 814 may be similar to any of the reflective structures and/or measurement systems described herein. For instance, in some examples, the reflective structure 814 may include one or more reflectors, such as a first reflector 816A and a second reflector 816B (collectively, “reflectors 816”). It should be understood that, although depicted and described as having first reflector 816A and second reflector 816B, the reflector 816 of the reflective structure 814 may have any suitable shape, configuration, and/or the like. By way of non-limiting example, the reflective structure 814 may have any of the configurations described above with reference to FIGS. 2A-2D.

In some examples, the array 803 of electromagnetic radiation sources 804 may provide emission of one or more electromagnetic radiation signals 806 to the workpiece 102 such that each of the one or more electromagnetic radiation signals 806 at least partially transmit all the way through the workpiece 102 for a plurality of transmission instances. The one or more electromagnetic radiation signals 806 may be received by the array 809 of detectors 810 following the plurality of transmission instances. In this manner, the system 800 may have a measurement area across the workpiece 102 that includes approximately a full surface area (e.g., of major surfaces 102-1, 102-2) of the workpiece 102.

More particularly, like the systems 100, 200, 300, 400, 500, 600, 700 (FIGS. 1, 3-8), the system 800 may include one or more processors (not shown) (e.g., processor(s) 122 (FIG. 1)) configured to determine one or more characteristics of the workpiece 102 based at least in part on the one or more electromagnetic radiation signals 806 received by the array 809 of detectors 810. More particularly, the one or more processors (not shown) (e.g., processor(s) 122 (FIG. 1)) may be configured to determine a spectroscopy metric of the workpiece 102, such as any of the spectroscopy metrics described herein, and/or one or surface features of the workpiece 102, such as any of the surfaces features described herein, based at least in part on the one or more electromagnetic radiation signals 806 received by the array 809. In some examples, the one or more processors (not shown) (e.g., processor(s) 122 (FIG. 1)) may be further configured to determine a characteristic distribution across the workpiece 102 based at least in part on the spectroscopy metric and/or the one or more surface features.

FIGS. 1-9 depict example systems 100, 200, 300, 400, 500, 600, 700, 800 for purposes of illustration and discussion. Those having ordinary skill in the art, using the disclosures provided herein, will understand that systems and apparatuses having different configurations may be used without deviating from the scope of the present disclosure.

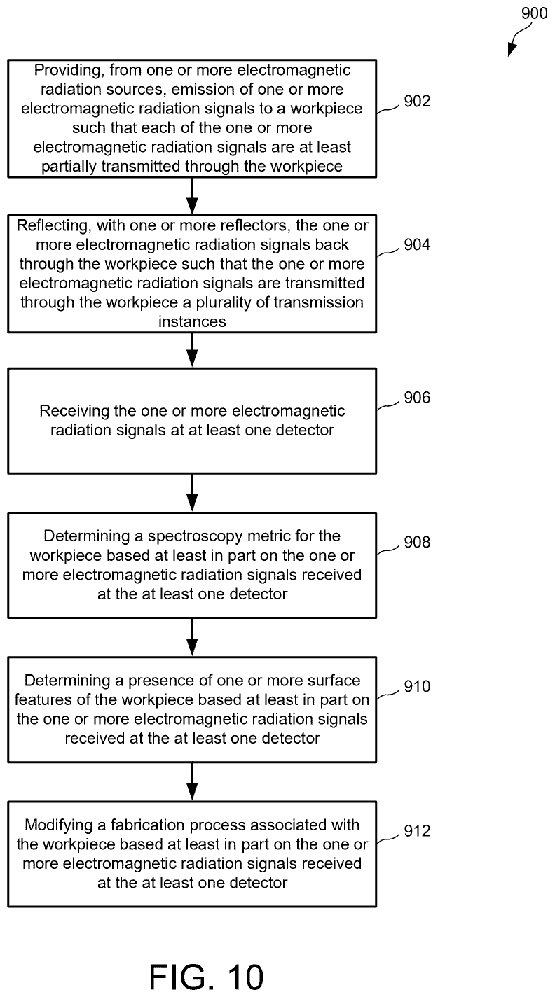

FIG. 10 depicts a flow chart diagram of an example method 900 according to example embodiments of the present disclosure. FIG. 10 depicts example process steps for purposes of illustration and discussion. Those having ordinary skill in the art, using the disclosures provided herein, will understand that the process steps of any of the methods described in the present disclosure may be adapted, modified, include steps not illustrated, omitted, and/or rearranged without deviating from the scope of the present disclosure.

At 902, the method 900 includes providing, from one or more electromagnetic radiation sources, emission of one or more electromagnetic radiation signals to a workpiece such that each of the one or more electromagnetic radiation signals are at least partially transmitted all the way through the workpiece. In some examples, the workpiece may have an absorption coefficient for the one or more electromagnetic radiation signals of less than about 10 percent. For instance, in some examples, the workpiece may be a silicon carbide semiconductor workpiece (e.g., a high-transparency silicon carbide wafer), a sapphire workpiece, a glass workpiece, a moissanite workpiece, a diamond workpiece, a quartz workpiece, an alumina workpiece, and/or the like. Furthermore, in some examples, the workpiece may have a diameter in a range of about 50 millimeters to about 300 millimeters, such as a range of about 125 millimeters to about 275 millimeters, such as a range of about 150 millimeters to about 200 millimeters. Additionally and/or alternatively, in some examples, the workpiece may have a workpiece area in a range of about 20 square centimeters (cm²) to about 800 square centimeters (cm²), such as about 100 square centimeters (cm²) to about 600 square centimeters (cm²), such as about 150 square centimeters (cm²) to about 400 square centimeters (cm²).

The one or more electromagnetic radiation sources may include one or more lasers, one or more monochromatic light sources (e.g., one or more high-intensity light-emitting diodes (LEDs), and/or the like. More particularly, in some examples, the one or more electromagnetic radiation sources may emit electromagnetic radiation in an infrared (IR) wavelength band, which includes wavelengths in a range of about 750 nanometers to about 25 microns. Additionally and/or alternatively, in some examples, the one or more electromagnetic radiation sources may emit electromagnetic radiation in a visible light wavelength band, which includes wavelengths in a range of about 400 nanometers to about 750 nanometers. Additionally and/or alternatively, in some examples, the one or more electromagnetic radiation sources may emit electromagnetic radiation in an ultraviolet (UV) wavelength band, which includes wavelengths in a range of about 1 nanometer to about 400 nanometers.

As described above, in some examples, a first electromagnetic radiation source of the one or more electromagnetic radiation sources may provide emission of a first electromagnetic radiation signal, a second electromagnetic radiation source of the one or more electromagnetic radiation sources may provide emission of a second electromagnetic radiation signal, and a third electromagnetic radiation source of the one or more electromagnetic radiation sources may provide emission of a third electromagnetic radiation signal.

In such examples, the first electromagnetic radiation source may be an infrared (IR) radiation source emitting one or more electromagnetic radiation signals in an IR spectral band (e.g., IR wavelength band), and the first electromagnetic radiation signal may have a wavelength within the IR spectral band. Additionally and/or alternatively, the first electromagnetic radiation source may be a blue laser radiation source emitting one or more electromagnetic radiation signals in a blue spectral band, and the first electromagnetic radiation signal may have a wavelength within the blue spectral band. Those having ordinary skill in the art will understand that the blue spectral band includes wavelengths in a range of about 400 nanometers to about 500 nanometers.

Furthermore, the second electromagnetic radiation source may be a visible light radiation source emitting one or more electromagnetic radiation signals in a visible light spectral band (e.g., visible light wavelength band), and the second electromagnetic radiation signal may have a wavelength within the visible light spectral band. Additionally and/or alternatively, the second electromagnetic radiation source may be a green laser radiation source emitting one or more electromagnetic radiation signals in a green spectral band, and the second electromagnetic radiation signal may have a wavelength within the green spectral band. Those having ordinary skill in the art will understand that the green spectral band includes wavelengths in a range of about 500 nanometers to about 570 nanometers.

Even further, the third electromagnetic radiation source may be an ultraviolet (UV) radiation source emitting one or more electromagnetic radiation signals in a UV spectral band (e.g., UV wavelength band), and the third electromagnetic radiation signal may have a wavelength within the UV spectral band. Additionally and/or alternatively, the third electromagnetic radiation source may be a red laser radiation source emitting one or more electromagnetic radiation signals in a red spectral band, and the third electromagnetic radiation signal may have a wavelength within the red spectral band. Those having ordinary skill in the art will understand that the red spectral band includes wavelengths in a range of about 620 nanometers to about 750 nanometers.

At 904, the method 900 includes reflecting, with one or more reflectors, the one or more electromagnetic radiation signals back through the workpiece such that the one or more electromagnetic radiation signals are transmitted through the workpiece a plurality of transmission instances. As described above, a transmission instance corresponds to each instance the one or more electromagnetic radiation signals (e.g., provided at 902) at least partially transmit all the way through the workpiece. In some examples, each transmission instance of the plurality of transmission instances may occur at a different location on the workpiece and may define a total measurement area for the workpiece. For instance, in some examples, the total measurement area includes about 10 percent of a surface area of a major surface of the workpiece. Furthermore, in some examples, the one or more electromagnetic radiation sources may be stationary for the plurality of transmission instances. In other examples, the one or more electromagnetic radiation sources may move during the plurality of transmission instances.

In some examples, the workpiece may be provided in a measurement system, and the measurement system may include one or more reflectors. The one or more reflectors may be in an optical path associated with the one or more electromagnetic radiation sources. Each of the one or more reflectors may have one of a flat shape, an elliptical shape, a parabolic shape, a curved shape, and/or the like.

In some examples, the measurement system may include a first reflector in parallel with a second reflector. The first reflector and the second reflector may be in an optical path associated with the one or more electromagnetic radiation sources, and the workpiece may be between the first reflector and the second reflector. In some examples, the one or more electromagnetic radiation sources may provide emission of the one or more electromagnetic radiation signals to the measurement system through a channel in the first reflector, and each of the one or more electromagnetic radiation signals may at least partially transmit all the way through the workpiece and reflect off the second reflector.

At 906, the method 900 includes receiving the one or more electromagnetic radiation signals at at least one detector. The at least one detector may be at least one charge-coupled device (CCD) detector, at least one photomultiplier tube (PMT), and/or the like. In some examples, subsequent to the plurality of transmission instances, the one or more electromagnetic radiation signals may be filtered by an optical filter between the workpiece and the at least one detector. Subsequent to filtering the one or more electromagnetic radiation signals, the one or more electromagnetic radiation signals may be received at the at least one detector.

At 908, the method 900 includes determining a spectroscopy metric for the workpiece based at least in part on the one or more electromagnetic radiation signals received at the at least one detector. As described above, the spectroscopy metric may include an optical absorption metric for the workpiece, an optical density of the workpiece, a transmittance of the workpiece, an optical reflectance of the workpiece, and/or the like.

At 910, the method 900 includes determining a presence of one or more surface features of the workpiece based at least in part on the one or more electromagnetic radiation signals received at the at least one detector. As described above, the one or more surface features may include a surface roughness of the workpiece, a parallelism of the workpiece, an optical wedge on one or more of the surfaces of the workpiece, and/or the like.

At 912, the method 900 includes modifying a fabrication process associated with the workpiece based at least in part on the one or more electromagnetic radiation signals received at the at least one detector. By way of non-limiting example, the workpiece may be fabricated into a window, a lens, an optical waveguide, and/or the like, and the fabrication process may be modified based at least in part on the one or more electromagnetic radiation signals received by the at least one detector.

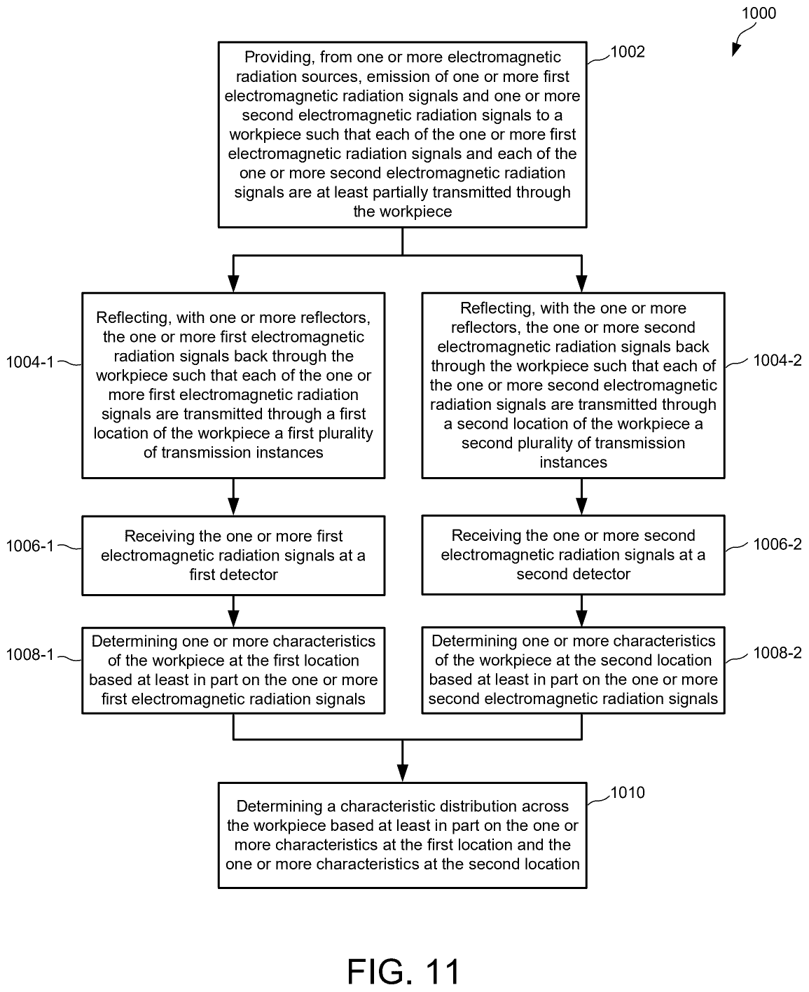

FIG. 11 depicts a flow chart diagram of an example method 1000 according to example embodiments of the present disclosure. FIG. 11 depicts example process steps for purposes of illustration and discussion. Those having ordinary skill in the art, using the disclosures provided herein, will understand that the process steps of any of the methods described in the present disclosure may be adapted, modified, include steps not illustrated, omitted, and/or rearranged without deviating from the scope of the present disclosure.

At 1002, the method 1000 may include providing, from one or more electromagnetic radiation sources, emission of one or more first electromagnetic radiation signals and one or more second electromagnetic radiation signals to a workpiece such that each of the one or more first electromagnetic radiation signals and each of the one or more second electromagnetic radiation signals are at least partially transmitted all the way through the workpiece. In some examples, the one or more electromagnetic radiation sources may emit electromagnetic radiation in an infrared (IR) wavelength band, a visible light wavelength band, and/or an ultraviolet (UV) wavelength band. Additionally and/or alternatively, in some examples, the one or more electromagnetic radiation sources may include a blue laser radiation source emitting one or more electromagnetic radiation signals in a blue spectral band, a green laser radiation source emitting one or more electromagnetic radiation signals in a green spectral band, and/or a red laser radiation source emitting one or more electromagnetic radiation signals in a red spectral band. Additionally and/or alternatively, in some examples, the one or more electromagnetic radiation sources may include one or more high-intensity light-emitting diodes (LEDs).

At 1004-1, the method 1000 may include reflecting, with one or more reflectors, the one or more first electromagnetic radiation signals back through the workpiece such that each of the one or more first electromagnetic radiation signals are transmitted through a first location of the workpiece a first plurality of transmission instances. As described above, a transmission instance of the first plurality of transmission instances may correspond to each instance the one or more first electromagnetic radiation signals at least partially transmit all the way through the workpiece at the first location.

Subsequent to the first plurality of transmission instances at 1004-1, the method 1000 may include, at 1006-1, receiving the one or more first electromagnetic radiation signals at a first detector and, at 1008-1, determining one or more characteristics of the workpiece at the first location based at least in part on the one or more first electromagnetic radiation signals. For instance, as described above, the one or more characteristics may include a spectroscopy metric for the workpiece at the first location (e.g., an optical absorption metric for the workpiece at the first location, an optical density of the workpiece at the first location, a transmittance of the workpiece at the first location, an optical reflectance of the workpiece at the first location, and/or the like) and/or one or more surface features for the workpiece at the first location (e.g., a surface roughness of the workpiece at the first location, a parallelism of the workpiece at the first location, an optical wedge on one or more of the surfaces of the workpiece at the first location, and/or the like).

At 1004-2, the method 1000 may include reflecting, with the one or more reflectors, the one or more second electromagnetic radiation signals back through the workpiece such that each of the one or more second electromagnetic radiation signals are transmitted through a second location of the workpiece a second plurality of transmission instances. As described above, a transmission instance of the second plurality of transmission instances may correspond to each instance the one or more second electromagnetic radiation signals at least partially transmit all the way through the workpiece at the second location. Furthermore, the first location and the second location may be different locations on the workpiece.

Subsequent to the second plurality of transmission instances at 1004-2, the method 1000 may include, at 1006-2, receiving the one or more second electromagnetic radiation signals at a second detector and, at 1008-2, determining one or more characteristics of the workpiece at the second location based at least in part on the one or more second electromagnetic radiation signals. For instance, as described above, the one or more characteristics may include a spectroscopy metric for the workpiece at the second location (e.g., an optical absorption metric for the workpiece at the second location, an optical density of the workpiece at the second location, a transmittance of the workpiece at the second location, an optical reflectance of the workpiece at the second location, and/or the like) and/or one or more surface features for the workpiece at the second location (e.g., a surface roughness of the workpiece at the second location, a parallelism of the workpiece at the second location, an optical wedge on one or more of the surfaces of the workpiece at the second location, and/or the like).

At 1010, the method 1000 may include determining a characteristic distribution across the workpiece based at least in part on the one or more characteristics at the first location (at 1008-1) and the one or more characteristics at the second location (at 1008-2). For instance, in some examples, the characteristic distribution may include a spectroscopy metric distribution across the workpiece based at least in part on the spectroscopy metrics at the first location and the spectroscopy metrics at the second location. Additionally and/or alternatively, the characteristic distribution may include a surface feature distribution across the workpiece based at least in part on the surface features at the first location and the surface features at the second location.

Example aspects of the present disclosure are set forth below. Any of the below features or examples may be used in combination with any of the embodiments or features provided in the present disclosure.

In one aspect, the present disclosure provides an example method. In some implementations, the example method includes providing, from one or more electromagnetic radiation sources, emission of one or more electromagnetic radiation signals to a workpiece such that each of the one or more electromagnetic radiation signals are at least partially transmitted through the workpiece. In some implementations, the example method includes reflecting, with one or more reflectors, the one or more electromagnetic radiation signals back through the workpiece such that the one or more electromagnetic radiation signals are transmitted through the workpiece a plurality of transmission instances. In some implementations, the example method includes receiving the one or more electromagnetic radiation signals at at least one detector.

In some implementations of the example method, the workpiece has an absorption coefficient for the one or more electromagnetic radiation signals of less than about 10 percent.

In some implementations, the example method includes modifying a fabrication process associated with the workpiece based at least in part on the one or more electromagnetic radiation signals received at the at least one detector.

In some implementations, the example method includes determining a spectroscopy metric for the workpiece based at least in part on the one or more electromagnetic radiation signals received at the at least one detector.

In some implementations of the example method, the spectroscopy metric includes an optical absorption metric of the workpiece.

In some implementations of the example method, the spectroscopy metric includes an optical density of the workpiece.

In some implementations of the example method, the spectroscopy metric includes a transmittance of the workpiece.

In some implementations of the example method, the spectroscopy metric includes an optical reflectance of the workpiece.

In some implementations of the example method, a transmission instance corresponds to each instance the one or more electromagnetic radiation signals at least partially transmit through the workpiece.

In some implementations of the example method, each transmission instance of the plurality of transmission instances occurs at a different location on the workpiece.

In some implementations of the example method, the plurality of transmission instances define a total measurement area for the workpiece, and the total measurement area includes at least about 10 percent of a surface area of a major surface the workpiece.

In some implementations of the example method, a first plurality of transmission instances of the plurality of transmission instances occurs at a first location on the workpiece and a second plurality of transmission instances of the plurality of transmission instances occurs at a second location on the workpiece.

In some implementations of the example method, providing emission of the one or more electromagnetic radiation signals to the workpiece includes providing, from a first electromagnetic radiation source, emission of one or more first electromagnetic radiation signals to the workpiece such that each of the one or more first electromagnetic radiation signals are at least partially transmitted through the workpiece at the first location for the first plurality of transmission instances. In some implementations of the example method, providing emission of the one or more electromagnetic radiation signals to the workpiece includes providing, from a second electromagnetic radiation source, emission of one or more second electromagnetic radiation signals to the workpiece such that each of the one or more second electromagnetic radiation signals are at least partially transmitted through the workpiece at the second location for the second plurality of transmission instances.

In some implementations, the example method includes, subsequent to the first plurality of transmission instances, receiving the one or more first electromagnetic radiation signals at a first detector. In some implementations, the example method includes, subsequent to the first plurality of transmission instances, determining one or more characteristics of the workpiece at the first location. In some implementations, the example method includes, subsequent to the second plurality of transmission instances, receiving the one or more second electromagnetic radiation signals at a second detector. In some implementations, the example method includes, subsequent to the second plurality of transmission instances, determining one or more characteristics of the workpiece at the second location. In some implementations, the example method includes determining a characteristic distribution across the workpiece based at least in part on the one or more characteristics at the first location and the one or more characteristics at the second location.

In some implementations of the example method, receiving the one or more electromagnetic radiation signals at the at least one detector includes, subsequent to a first plurality of transmission instances of the plurality of transmission instances, determining one or more characteristics of the workpiece at a first location of the workpiece based at least in part on one or more electromagnetic radiation signals received at a first detector, the first plurality of transmission instances occurring at the first location. In some implementations of the example method, receiving the one or more electromagnetic radiation signals at the at least one detector includes, subsequent to a second plurality of transmission instances of the plurality of transmission instances, determining one or more characteristics of the workpiece at a second location of the workpiece based at least in part on one or more electromagnetic radiation signals received at a second detector, the second plurality of transmission instances occurring at the second location. In some implementations of the example method, receiving the one or more electromagnetic radiation signals at the at least one detector includes determining a characteristic distribution across the workpiece based at least in part on the one or more characteristics at the first location and the one or more characteristics at the second location.

In some implementations of the example method, providing emission of the one or more electromagnetic radiation signals to the workpiece includes providing, from a first electromagnetic radiation source, emission of a first electromagnetic radiation signal. In some implementations of the example method, providing emission of the one or more electromagnetic radiation signals to the workpiece includes providing, from a second electromagnetic radiation source, emission of a second electromagnetic radiation signal. In some implementations of the example method, each of the first electromagnetic radiation signal and the second electromagnetic radiation signal are at least partially transmitted through the workpiece for the plurality of transmission instances.

In some implementations of the example method, providing emission of the one or more electromagnetic radiation signals to the workpiece further includes providing, from a third electromagnetic radiation source, emission of a third electromagnetic radiation signal. In some implementations of the example method, providing emission of the one or more electromagnetic radiation signals to the workpiece further includes wherein the third electromagnetic radiation signal is at least partially transmitted through the workpiece for the plurality of transmission instances.

In some implementations of the example method, the first electromagnetic radiation source is an infrared (IR) radiation source emitting one or more electromagnetic radiation signals in an IR spectral band, the first electromagnetic radiation signal having a wavelength within the IR spectral band. In some implementations of the example method, the second electromagnetic radiation source is a visible light radiation source emitting one or more electromagnetic radiation signals in a visible light spectral band, the second electromagnetic radiation signal having a wavelength within the visible light spectral band. In some implementations of the example method, the third electromagnetic radiation source is an ultraviolet (UV) radiation source emitting one or more electromagnetic radiation signals in a UV spectral band, the third electromagnetic radiation signal having a wavelength within the UV spectral band.

In some implementations of the example method, the first electromagnetic radiation source is a blue laser radiation source emitting one or more electromagnetic radiation signals in a blue spectral band, the first electromagnetic radiation signal having a wavelength within the blue spectral band. In some implementations of the example method, the second electromagnetic radiation source is a green laser radiation source emitting one or more electromagnetic radiation signals in a green spectral band, the second electromagnetic radiation signal having a wavelength within the green spectral band. In some implementations of the example method, the third electromagnetic radiation source is a red laser radiation source emitting one or more electromagnetic radiation signals in a red spectral band, the third electromagnetic radiation signal having a wavelength within the red spectral band.

In some implementations of the example method, the blue spectral band includes wavelengths in a range of about 400 nanometers to about 500 nanometers. In some implementations of the example method, the green spectral band includes wavelengths in a range of about 500 nanometers to about 570 nanometers. In some implementations of the example method, the red spectral band includes wavelengths in a range of about 620 nanometers to about 750 nanometers.

In some implementations of the example method, the one or more electromagnetic radiation sources are stationary for the plurality of transmission instances.

In some implementations of the example method, the one or more electromagnetic radiation sources emit electromagnetic radiation in an infrared (IR) wavelength band.

In some implementations of the example method, the IR wavelength band includes wavelengths in a range of about 750 nanometers to about 25 microns.

In some implementations of the example method, the one or more electromagnetic radiation sources emit electromagnetic radiation across a visible light wavelength band.

In some implementations of the example method, the visible light wavelength band includes wavelengths in a range of about 400 nanometers to about 750 nanometers,

In some implementations of the example method, the one or more electromagnetic radiation sources emit electromagnetic radiation across an ultraviolet (UV) wavelength band.

In some implementations of the example method, the UV wavelength band includes wavelengths in a range of about 1 nanometer to about 400 nanometers.

In some implementations, the example method includes determining a presence of one or more surface features of the workpiece based at least in part on the one or more electromagnetic radiation signals received at the at least one detector.

In some implementations of the example method, the one or more surface features comprise one or more of a surface roughness of the workpiece, a parallelism of the workpiece, or an optical wedge on one or more surfaces of the workpiece.

In some implementations of the example method, the workpiece is provided in a measurement system, the measurement system comprising the one or more reflectors, the one or more reflectors being in an optical path associated with the one or more electromagnetic radiation sources.

In some implementations of the example method, each of the one or more reflectors have one of a flat shape, an elliptical shape, a parabolic shape, or a curved shape.

In some implementations of the example method, the workpiece is provided in a measurement system, the measurement system comprising a first reflector of the one or more reflectors and a second reflector of the one or more reflectors, the first reflector being in parallel with the second reflector, and the first reflector and the second reflector are in an optical path associated with the one or more electromagnetic radiation sources.

In some implementations of the example method, the workpiece is between the first reflector and the second reflector of the measurement system.

In some implementations of the example method, providing emission of the one or more electromagnetic radiation signals to the workpiece includes providing emission of the one or more electromagnetic radiation signals to the measurement system through a channel in the first reflector, each of the one or more electromagnetic radiation signals at least partially transmitting through the workpiece and reflecting off the second reflector.

In some implementations of the example method, receiving the one or more electromagnetic radiation signals at the at least one detector includes, subsequent to the plurality of transmission instances, filtering, by an optical filter, the one or more electromagnetic radiation signals, the optical filter being between the workpiece and the at least one detector. In some implementations of the example method, receiving the one or more electromagnetic radiation signals at the at least one detector includes, subsequent to filtering the one or more electromagnetic radiation signals, receiving the one or more electromagnetic radiation signals at the at least one detector.

In some implementations of the example method, the at least one detector is at least one charge-coupled device (CCD) detector.

In some implementations of the example method, the at least one detector is at least one photomultiplier tube (PMT).

In some implementations of the example method, the workpiece is a silicon carbide semiconductor workpiece.

In some implementations of the example method, the silicon carbide semiconductor workpiece has a diameter in a range of about 50 millimeters to about 300 millimeters.

In some implementations of the example method, the silicon carbide semiconductor workpiece has a diameter in a range of about 125 millimeters to about 275 millimeters.

In some implementations of the example method, the silicon carbide semiconductor workpiece has a diameter in a range of about 150 millimeters to about 200 millimeters.

In some implementations of the example method, the silicon carbide semiconductor workpiece has a workpiece area in a range of about 20 square centimeters (cm²) to about 800 square centimeters (cm²).

In some implementations of the example method, the workpiece is one of a sapphire workpiece, a glass workpiece, a moissanite workpiece, a diamond workpiece, a quartz workpiece, or an alumina workpiece.

In some implementations of the example method, the one or more electromagnetic radiation sources comprise one or more lasers.

In some implementations of the example method, the workpiece is a high-transparency silicon carbide wafer.

In some implementations of the example method, the one or more electromagnetic radiation sources comprise one or more monochromatic light sources.

In some implementations of the example method, the one or more monochromatic light sources includes one or more high-intensity light-emitting diodes (LEDs).

In another aspect, the present disclosure provides an example system. In some implementations, the example system includes one or more light sources operable to provide one or more light signals. In some implementations, the example system includes a workpiece holder operable to hold a semiconductor workpiece in an optical path of the one or more light sources such that each of the one or more light signals are at least partially transmitted through the semiconductor workpiece for a plurality of transmission instances. In some implementations, the example system includes one or more detectors operable to receive the one or more light signals subsequent to the plurality of transmission instances.

In some implementations of the example system, the semiconductor workpiece has an absorption coefficient for the one or more light signals of less than about 10 percent.

In some implementations of the example system, a transmission instance corresponds to each instance the one or more light signals at least partially transmit through the semiconductor workpiece.

In some implementations of the example system, each transmission instance of the plurality of transmission instances occurs at a different location on the semiconductor workpiece.

In some implementations of the example system, the plurality of transmission instances define a total measurement area for the semiconductor workpiece, and the total measurement area includes at least about 10 percent of a surface area of a major surface of the semiconductor workpiece.

In some implementations, the example system further includes a measurement system, the measurement system comprising one or more reflectors in the optical path of the one or more light sources.

In some implementations of the example system, each of the one or more reflectors have one of a flat shape, an elliptical shape, a parabolic shape, or a curved shape.

In some implementations of the example system, the measurement system includes a first reflector in parallel with a second reflector, and the workpiece holder is between the first reflector and the second reflector.

In some implementations of the example system, the one or more light sources are operable to provide the one or more light signals to the measurement system through a channel in the first reflector, each of the one or more light signals at least partially transmitting through the semiconductor workpiece and reflecting off the second reflector.

In some implementations of the example system, subsequent to the plurality of transmission instances, the one or more detectors are operable to receive the one or more light signals through a channel in the second reflector.

In some implementations, the example system includes one or more processors configured to determine a spectroscopy metric for the semiconductor workpiece based at least in part on the one or more light signals received by the one or more detectors.

In some implementations of the example system, the spectroscopy metric includes one or more of an optical absorption metric for the semiconductor workpiece, an optical density of the semiconductor workpiece, a transmittance of the semiconductor workpiece, or an optical reflectance of the semiconductor workpiece.

In some implementations of the example system, the one or more processors are further configured to determine a presence of one or more surface features of the semiconductor workpiece based at least in part on the one or more light signals received by the one or more detectors.

In some implementations of the example system, the one or more surface features comprise one or more of a surface roughness of the semiconductor workpiece, a parallelism of the semiconductor workpiece, or an optical wedge on one or more surfaces of the semiconductor workpiece.

In some implementations, the example system further includes one or more optical filters between the semiconductor workpiece and the one or more detectors.

In some implementations of the example system, the one or more detectors are one or more charge-coupled device (CCD) detectors.

In some implementations of the example system, the one or more detectors are one or more photomultiplier tubes (PMTs).

In some implementations of the example system, the semiconductor workpiece is a crystalline silicon carbide semiconductor workpiece.

In some implementations of the example system, the crystalline silicon carbide semiconductor workpiece is a high-transparency silicon carbide wafer.

In some implementations of the example system, the crystalline silicon carbide semiconductor workpiece has a diameter in a range of about 50 millimeters to about 300 millimeters.

In some implementations of the example system, the crystalline silicon carbide semiconductor workpiece has a diameter in a range of about 125 millimeters to about 275 millimeters.

In some implementations of the example system, the crystalline silicon carbide semiconductor workpiece has a diameter in a range of about 150 millimeters to about 200 millimeters.

In some implementations of the example system, the crystalline silicon carbide semiconductor workpiece has a workpiece area in a range of about 20 square centimeters (cm²) to about 800 square centimeters (cm²).

In some implementations of the example system, the semiconductor workpiece is one of a sapphire workpiece, a glass workpiece, a moissanite workpiece, a diamond workpiece, a quartz workpiece, or an alumina workpiece.

In some implementations of the example system, the one or more light sources are one or more lasers.

In some implementations, the example system includes at least one blue laser emitting one or more light signals in a blue spectral band. In some implementations, the example system includes at least one green laser emitting one or more light signals in a green spectral band. In some implementations, the example system includes at least one red laser emitting one or more light signals in a red spectral band.

In some implementations of the example system, the blue spectral band includes wavelengths in a range of about 400 nanometers to about 500 nanometers. In some implementations of the example system, the green spectral band includes wavelengths in a range of about 500 nanometers to about 570 nanometers. In some implementations of the example system, the red spectral band includes wavelengths in a range of about 620 nanometers to about 750 nanometers.

In some implementations of the example system, the one or more light sources are stationary for the plurality of transmission instances.

In some implementations of the example system, the one or more light sources emit electromagnetic radiation across an infrared (IR) wavelength band.

In some implementations of the example system, the IR wavelength band includes wavelengths in a range of about 750 nanometers to about 25 microns.

In some implementations of the example system, the one or more light sources emit electromagnetic radiation across a visible light wavelength band.

In some implementations of the example system, the visible light wavelength band includes wavelengths in a range of about 400 nanometers to about 750 nanometers.

In some implementations of the example system, the one or more light sources emit electromagnetic radiation across an ultraviolet (UV) wavelength band.

In some implementations of the example system, the UV wavelength band includes wavelengths in a range of about 1 nanometer to about 400 nanometers.

In some implementations of the example system, the one or light sources comprise one or more monochromatic light sources.

In some implementations of the example system, the one or more monochromatic light sources includes one or more high-intensity light-emitting diodes (LEDs).

In another aspect, the present disclosure provides an example system. In some implementations, the example system includes a reflective structure comprising one or more reflectors. In some implementations, the example system includes one or more light sources operable to provide one or more light signals through a first channel of the reflective structure. In some implementations, the example system includes a workpiece holder operable to hold a workpiece in an optical path of the one or more light sources such that each of the one or more light signals at least partially transmit through the workpiece for a plurality of transmission instances. In some implementations, the example system includes one or more detectors operable to receive the one or more light signals through a second channel of the reflective structure subsequent to the plurality of transmission instances.

In some implementations of the example system, the workpiece has an absorption coefficient for the one or more light signals of less than about 10 percent.

In some implementations of the example system, the reflective structure includes a first reflector in parallel with a second reflector, and the workpiece holder is between the first reflector and the second reflector of the reflective structure.

In some implementations, the example system includes one or more processors configured to determine a spectroscopy metric for the workpiece based at least in part on the one or more light signals received by the one or more detectors.

In some implementations of the example system, the spectroscopy metric includes one or more of an optical absorption metric for the workpiece, an optical density of the workpiece, a transmittance of the workpiece, or an optical reflectance of the workpiece.

In some implementations of the example system, the one or more processors are further configured to determine a presence of one or more surface features of the workpiece based at least in part on the one or more light signals received by the one or more detectors.

In some implementations of the example system, the one or more surface features comprise one or more of a surface roughness of the workpiece, a parallelism of the workpiece, or an optical wedge on one or more surfaces of the workpiece.

In some implementations, the example system further includes one or more optical filters between the workpiece and the one or more detectors.

In some implementations of the example system, the one or more detectors are one or more charge-coupled device (CCD) detectors.

In some implementations of the example system, the one or more detectors are one or more photomultiplier tubes (PMTs).

In some implementations of the example system, the workpiece has a diameter in a range of about 50 millimeters to about 300 millimeters.

In some implementations of the example system, the workpiece has a workpiece area in a range of about 20 square centimeters (cm²) to about 800 square centimeters (cm²).

In some implementations of the example system, the one or more light sources comprise at least one blue laser emitting one or more light signals in a blue spectral band, the blue spectral band comprising wavelengths in a range of about 400 nanometers to about 500 nanometers. In some implementations of the example system, the one or more light sources comprise at least one green laser emitting one or more light signals in a green spectral band, the green spectral band comprising wavelengths in a range of about 500 nanometers to about 570 nanometers. In some implementations of the example system, the one or more light sources comprise at least one red laser emitting one or more light signals in a red spectral band, the red spectral band comprising wavelengths in a range of about 620 nanometers to about 750 nanometers.

In some implementations of the example system, the one or more light sources emit electromagnetic radiation across an infrared (IR) wavelength band, the IR wavelength band comprising wavelengths in a range of about 750 nanometers to about 25 microns.

In some implementations of the example system, the one or more light sources emit electromagnetic radiation across a visible light wavelength band, the visible light wavelength band comprising wavelengths in a range of about 400 nanometers to about 750 nanometers.

In some implementations of the example system, the one or more light sources emit electromagnetic radiation across an ultraviolet (UV) wavelength band, the UV wavelength band comprising wavelengths in a range of about 1 nanometer to about 400 nanometers.

In some implementations of the example system, the one or more light sources comprise one or more high-intensity light-emitting diodes (LEDs).

In some implementations of the example system, the workpiece is a silicon carbide semiconductor workpiece.

In some implementations of the example system, the silicon carbide semiconductor workpiece has a diameter in a range of about 50 millimeters to about 300 millimeters.

In some implementations of the example system, the silicon carbide semiconductor workpiece has a diameter in a range of about 125 millimeters to about 275 millimeters.

In some implementations of the example system, the silicon carbide semiconductor workpiece has a diameter in a range of about 150 millimeters to about 200 millimeters.

In some implementations of the example system, the workpiece is one of a sapphire workpiece, a glass workpiece, a moissanite workpiece, a diamond workpiece, a quartz workpiece, or an alumina workpiece.

In some implementations of the example system, the workpiece is a high-transparency silicon carbide wafer.

In another aspect, the present disclosure provides an example method. In some implementations, the example method includes providing, from one or more electromagnetic radiation sources, emission of one or more first electromagnetic radiation signals and one or more second electromagnetic radiation signals to a workpiece such that each of the one or more first electromagnetic radiation signals and each of the one or more second electromagnetic radiation signals are at least partially transmitted through the workpiece. In some implementations, the example method includes reflecting, with one or more reflectors, the one or more first electromagnetic radiation signals back through the workpiece such that each of the one or more first electromagnetic radiation signals are transmitted through a first location of the workpiece a first plurality of transmission instances. In some implementations, the example method includes reflecting, with the one or more reflectors, the one or more second electromagnetic radiation signals back through the workpiece such that each of the one or more second electromagnetic radiation signals are transmitted through a second location of the workpiece a second plurality of transmission instances. In some implementations, the example method includes, subsequent to the first plurality of transmission instances, receiving the one or more first electromagnetic radiation signals at a first detector and determining one or more characteristics of the workpiece at the first location based at least in part on the one or more first electromagnetic radiation signals. In some implementations, the example method includes, subsequent to the second plurality of transmission instances, receiving the one or more second electromagnetic radiation signals at a second detector and determining one or more characteristics of the workpiece at the second location based at least in part on the one or more second electromagnetic radiation signals.

In some implementations, the example method includes determining a characteristic distribution across the workpiece based at least in part on the one or more characteristics at the first location and the one or more characteristics at the second location.

In some implementations of the example method, a transmission instance of the first plurality of transmission instances corresponds to each instance the one or more first electromagnetic radiation signals at least partially transmit through the workpiece at the first location. In some implementations of the example method, a transmission instance of the second plurality of transmission instances corresponds to each instance the one or more second electromagnetic radiation signals at least partially transmit through the workpiece at the second location.

In some implementations of the example method, the first location and the second location are different locations on the workpiece.

In some implementations of the example method, the one or more characteristics of the workpiece include one or more surface features of the workpiece, the one or more surface features comprising one or more of a surface roughness of the workpiece, a parallelism of the workpiece, or an optical wedge on one or more surfaces of the workpiece.

In some implementations of the example method, the one or more characteristics of the workpiece include one or more spectroscopy metrics for the workpiece, the one or more spectroscopy metrics comprising one or more of an optical absorption metric of the workpiece, an optical density of the workpiece, a transmittance of the workpiece, or an optical reflectance of the workpiece.

In some implementations of the example method, the one or more electromagnetic radiation sources emit electromagnetic radiation in an infrared (IR) wavelength band, the IR wavelength band comprising wavelengths in a range of about 750 nanometers to about 25 microns.

In some implementations of the example method, the one or more electromagnetic radiation sources emit electromagnetic radiation across a visible light wavelength band, the visible light wavelength band comprising wavelengths in a range of about 400 nanometers to about 750 nanometers.

In some implementations of the example method, the one or more electromagnetic radiation sources emit electromagnetic radiation across an ultraviolet (UV) wavelength band, the UV wavelength band comprising wavelengths in a range of about 1 nanometer to about 400 nanometers.

In some implementations of the example method, the one or more electromagnetic radiation sources comprise one or more of: a blue laser radiation source emitting one or more electromagnetic radiation signals in a blue spectral band, the blue spectral band comprising wavelengths in a range of about 400 nanometers to about 500 nanometers; a green laser radiation source emitting one or more electromagnetic radiation signals in a green spectral band, the green spectral band comprising wavelengths in a range of about 500 nanometers to about 570 nanometers; or a red laser radiation source emitting one or more electromagnetic radiation signals in a red spectral band, the red spectral band comprising wavelengths in a range of about 620 nanometers to about 750 nanometers.

In some implementations of the example method, the one or more electromagnetic radiation sources comprise one or more high-intensity light-emitting diodes (LEDs).

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A method, comprising:
providing, from one or more electromagnetic radiation sources, emission of one or more electromagnetic radiation signals to a workpiece such that each of the one or more electromagnetic radiation signals are at least partially transmitted through the workpiece;
reflecting, with one or more reflectors, the one or more electromagnetic radiation signals back through the workpiece such that the one or more electromagnetic radiation signals are transmitted through the workpiece a plurality of transmission instances; and
receiving the one or more electromagnetic radiation signals at at least one detector.

2. The method of claim 1, further comprising:
modifying a fabrication process associated with the workpiece based at least in part on the one or more electromagnetic radiation signals received at the at least one detector.

3. The method of claim 1, further comprising:
determining a spectroscopy metric for the workpiece based at least in part on the one or more electromagnetic radiation signals received at the at least one detector.

4. The method of claim 3, wherein the spectroscopy metric comprises one or more of:
an optical absorption metric of the workpiece;
an optical density of the workpiece;
a transmittance of the workpiece; or
an optical reflectance of the workpiece.

5. The method of claim 1, wherein a transmission instance corresponds to each instance the one or more electromagnetic radiation signals at least partially transmit through the workpiece, and wherein each transmission instance of the plurality of transmission instances occurs at a different location on the workpiece.

6. The method of claim 5, wherein a first plurality of transmission instances of the plurality of transmission instances occurs at a first location on the workpiece and a second plurality of transmission instances of the plurality of transmission instances occurs at a second location on the workpiece.

7. The method of claim 5, wherein receiving the one or more electromagnetic radiation signals at the at least one detector comprises:
subsequent to a first plurality of transmission instances of the plurality of transmission instances, determining one or more characteristics of the workpiece at a first location of the workpiece based at least in part on one or more electromagnetic radiation signals received at a first detector, the first plurality of transmission instances occurring at the first location;
subsequent to a second plurality of transmission instances of the plurality of transmission instances, determining one or more characteristics of the workpiece at a second location of the workpiece based at least in part on one or more electromagnetic radiation signals received at a second detector, the second plurality of transmission instances occurring at the second location; and
determining a characteristic distribution across the workpiece based at least in part on the one or more characteristics at the first location and the one or more characteristics at the second location.

8. The method of claim 1, wherein providing emission of the one or more electromagnetic radiation signals to the workpiece comprises:
providing, from a first electromagnetic radiation source, emission of a first electromagnetic radiation signal; and
providing, from a second electromagnetic radiation source, emission of a second electromagnetic radiation signal,
wherein each of the first electromagnetic radiation signal and the second electromagnetic radiation signal are at least partially transmitted through the workpiece for the plurality of transmission instances.

9. The method of claim 8, wherein providing emission of the one or more electromagnetic radiation signals to the workpiece further comprises:
providing, from a third electromagnetic radiation source, emission of a third electromagnetic radiation signal,
wherein the third electromagnetic radiation signal is at least partially transmitted through the workpiece for the plurality of transmission instances.

10. The method of claim 9, wherein:
the first electromagnetic radiation source is an infrared (IR) radiation source emitting one or more electromagnetic radiation signals in an IR spectral band, the first electromagnetic radiation signal having a wavelength within the IR spectral band;
the second electromagnetic radiation source is a visible light radiation source emitting one or more electromagnetic radiation signals in a visible light spectral band, the second electromagnetic radiation signal having a wavelength within the visible light spectral band; and
the third electromagnetic radiation source is an ultraviolet (UV) radiation source emitting one or more electromagnetic radiation signals in a UV spectral band, the third electromagnetic radiation signal having a wavelength within the UV spectral band.

11. The method of claim 1, further comprising:
determining a presence of one or more surface features of the workpiece based at least in part on the one or more electromagnetic radiation signals received at the at least one detector,
wherein the one or more surface features comprising one or more of a surface roughness of the workpiece, a parallelism of the workpiece, or an optical wedge on one or more surfaces of the workpiece.

12. A system, comprising:
one or more light sources operable to provide one or more light signals;
a workpiece holder operable to hold a semiconductor workpiece in an optical path of the one or more light sources such that each of the one or more light signals are at least partially transmitted through the semiconductor workpiece for a plurality of transmission instances; and
one or more detectors operable to receive the one or more light signals subsequent to the plurality of transmission instances.

13. The system of claim 12, further comprising a measurement system, the measurement system comprising one or more reflectors in the optical path of the one or more light sources.

14. The system of claim 13, wherein the measurement system comprises a first reflector in parallel with a second reflector, and wherein the workpiece holder is between the first reflector and the second reflector.

15. The system of claim 14, wherein the one or more light sources are operable to provide the one or more light signals to the measurement system through a channel in the first reflector, each of the one or more light signals at least partially transmitting through the semiconductor workpiece and reflecting off the second reflector, and
wherein, subsequent to the plurality of transmission instances, the one or more detectors are operable to receive the one or more light signals through a channel in the second reflector.

16. The system of claim 12, wherein the semiconductor workpiece is one of a sapphire workpiece, a glass workpiece, a moissanite workpiece, a diamond workpiece, a quartz workpiece, or an alumina workpiece.

17. The system of claim 12, wherein the one or more light sources emit electromagnetic radiation across:
an infrared (IR) wavelength band, the IR wavelength band comprising wavelengths in a range of about 750 nanometers to about 25 microns;
a visible light wavelength band, the visible light wavelength band comprising wavelengths in a range of about 400 nanometers to about 750 nanometers; and
an ultraviolet (UV) wavelength band, the UV wavelength band comprising wavelengths in a range of about 1 nanometer to about 400 nanometers.

18. An system, comprising:
a reflective structure comprising one or more reflectors;
one or more light sources operable to provide one or more light signals through a first channel of the reflective structure;
a workpiece holder operable to hold a workpiece in an optical path of the one or more light sources such that each of the one or more light signals at least partially transmit through the workpiece for a plurality of transmission instances; and
one or more detectors operable to receive the one or more light signals through a second channel of the reflective structure subsequent to the plurality of transmission instances.

19. The system of claim 18, further comprising:
one or more processors configured to determine a spectroscopy metric for the workpiece based at least in part on the one or more light signals received by the one or more detectors, the spectroscopy metric comprising one or more of an optical absorption metric for the workpiece, an optical density of the workpiece, a transmittance of the workpiece, or an optical reflectance of the workpiece.

20. The system of claim 18, wherein the one or more light sources comprise:
at least one blue laser emitting one or more light signals in a blue spectral band, the blue spectral band comprising wavelengths in a range of about 400 nanometers to about 500 nanometers;
at least one green laser emitting one or more light signals in a green spectral band, the green spectral band comprising wavelengths in a range of about 500 nanometers to about 570 nanometers; and
at least one red laser emitting one or more light signals in a red spectral band, the red spectral band comprising wavelengths in a range of about 620 nanometers to about 750 nanometers.
